(19) United States
(12) Patent Application Publication
(10) Pub. No.: US 2025/0316438 A1
(43) Pub. Date: Oct. 9, 2025

(54) FIELD EMISSION ELECTRON SOURCE, METHOD OF PRODUCING SAME, AND ELECTRON BEAM DEVICE USING SAME

(71) Applicant: Hitachi High-Tech Corporation, Minato-ku, Tokyo (JP)

(72) Inventors: Toshiaki KUSUNOKI, Tokyo (JP); Tomihiro HASHIZUME, Tokyo (JP); Noriaki ARAI, Tokyo (JP); Masahiro FUKUTA, Tokyo (JP)

(21) Appl. No.: 18/865,028

(22) PCT Filed: Jun. 20, 2022
(86) PCT No.: PCT/JP2022/024469

§ 371 Date: Nov. 12, 2024

(51) Int. Cl. H01J 37/073; H01J 9/02

(52) U.S. Cl. CPC H01J 37/073; H01J 9/02

(57) ABSTRACT

A field emission electron source using a plane of a hexaboride single crystal or a transition metal carbide single crystal as an electron emission surface, to improve a ratio of a radiation angle current density to a total current and improve current stability. A first plane top facet is formed at a distal end of a tip of a hexaboride single crystal or a transition metal carbide single crystal with a <100> axis, the first plane top facet is surrounded by side facets that include at least four {n11} planes and at least four {n10} planes, and of which a total area of {n11} plane side facets is larger than a total area of {n10} plane side facets, and a microcrystal having a second plane top facet is formed on a plane of the first plane top facet, and electrons are mainly from the second plane top facet.

### TECHNICAL FIELD

The present invention relates to a field emission electron source of an electron beam device such as an electron microscope, a method for producing the field emission electron source, and an electron beam device using the field emission electron source.

### BACKGROUND ART

An electron microscope has spatial resolution exceeding an optical limit and can perform observation and a composition analysis for a microstructure in the order of nm to pm. Therefore, the electron microscope is widely used in engineering fields such as material, physics, medicine, biology, electric, and machine. The electron microscope includes a scanning electron microscope (SEM) serving as a device capable of easily observing a sample surface.

An electron source used in an electron beam device such as a scanning electron microscope includes a thermal electron source (a thermionic emitter: TE), a field emission electron source (a field emitter: FE), and a Schottky emission electron source (a Schottky emitter: SE). Among these electron sources, the field emission electron source (FE) can emit an electron beam having good monochromaticity and high luminance, can reduce chromatic aberration in an electron optical system, and is used as an electron source for a scanning electron microscope of high spatial resolution. A W tip using a {310} crystal plane of tungsten in which a distal end of a needle-shaped electrode (a tip) is sharpened is widely used as the field emission electron source.

FIG. 1 shows an energy diagram of an emission principle of the field emission electron source. By concentrating an external electric field F at the distal end of the W tip, a high electric field is applied, and electrons e at the W tip are quantum mechanically transmitted through an energy barrier that is effectively thinned and are emitted into vacuum. Since such an operation can be performed at room temperature, an energy full width at half maximum ΔE_{FE} of the drawn electrons e is as narrow as about 0.3 eV. Further, since an electron beam having a high density is emitted from a narrow electron emission surface at a very sharp distal end of the tip, such a field emission electron source has a feature of high luminance of 10⁸ (A/cm²sr).

In the field emission electron source, since the energy full width at half maximum ΔE is narrowed and luminance B is increased, a field emission electron source using a nanowire of hexaboride, such as LaB₆, which has a work function Φ lower than W, is proposed (for example, PTL 1). Since a work function barrier of the hexaboride is lower than that of W, electrons can be transmitted by a lower electric field and can be field-emitted, and the energy full width at half maximum ΔE_{FE} can be further reduced.

Previously, the inventors developed and disclosed a cold field emission electron source (a cold field emitter, CFE) in which a hexaboride single crystal such as CeB₆ produced by a floating zone method or the like was used, a distal end of the hexaboride single crystal was shaped into a hemispherical shape by electrolytic polishing, field evaporation, or the like, and further heating processing was performed at 700° C. to 1400° C. to form a {310} crystal plane of CeB₆ having a low work function, and field emission was performed at room temperature (PTL 2). The field emission electron source of the hexaboride single crystal has better monochromaticity than a field emission electron source using W in the related art, and when a ratio J_{Ω}/It of a radiation angle current density J_{Ω} (μA/sr) to a total current It (μA) is 6 (1/sr) to 13 (1/sr) or more, the radiation angle current density J_{Ω} (μA/sr) can be increased. According to this invention, in particular, it is possible to improve chromatic aberration of a scanning electron microscope at a low acceleration voltage, and it is possible to observe a polar surface of a sample and achieve high spatial resolution observation for a light element substance such as a carbon-based compound. In addition, since a size of the hexaboride single crystal produced by the floating zone method or the like is about 0.1 mm to several mm, the hexaboride single crystal can be assembled to an electron source using a human hand or a machine, and the hexaboride single crystal has an advantage of being more inexpensive, more convenient, and having higher yield than an electron source that uses a nanowire having a diameter of several tens to several hundreds of nm.

Further, as a result of studies of the inventors, it was found that when a (100) plane facet was formed on a top portion of a tip of a hexaboride single crystal having a <100> axis of a hexaboride single crystal, and field emission electrons from the (100) plane served as a probe, stability of an emission current was higher than that of field emission electrons from a {310} plane. The reason is that a work function of the (100) plane is slightly higher than that of the {310} plane, the work function is less likely to be affected by an adsorption gas, an atomic area density is higher than that of the {310} plane which makes a structure stable and prevents atom vibration, heating makes it easier to form a flat facet with a large area and reduce an electric field concentration level, further local changes in the work function caused by gas adsorption and desorption during field electron emission are averaged over a large surface of the facet and an overall fluctuation is reduced, and the like. Therefore, when the (100) plane facet is formed at the distal end of the tip of the hexaboride single crystal with the <100> axis, and an electron beam emitted from the (100) plane serves as a probe, current stability can be improved.

However, there are problems that since the work function is high and a concentration level of an electric field is lowered, the (100) plane is less likely to emit electrons as compared with the {310} plane, and since electrons emitted from planes such as the {310} plane formed on side portions of the tip around the (100) plane are wasted outside an optical axis of an electron microscope, a ratio of the radiation angle current density J_{Ω} (μA/sr) to the total current It (μA) is significantly reduced to less than 1 (1/sr).

When the total current It (μA) is too large, wasted electrons emitted to the outside of the optical axis are radiated onto an extraction electrode or the like in the electron microscope to generate an electron beam stimulation desorption gas from a surface of the electrode. The electron beam stimulation desorption gas is incident and adsorbed on a surface of a field emission electron source, which causes a change in the work function and impairs current stability.

Therefore, as a result of intensive studies of inventors to solve this problem, it was disclosed that a stable electron source can be achieved by forming a (100) plane top facet at a distal end of a tip of a hexaboride single crystal with a <100> axis for forming the electron source, the (100) plane top facet being surrounded by side facets including at least four {n11} planes having a high work function and at least four {n10} planes having a low work function, n being an integer of 1, 2, or 3, and by setting a total area of {n11} plane side facets to be larger than a total area of {n10} plane side facets, an amount of unnecessary current emitted from the side facets can be reduced, and a ratio of a radiation angle current density J_{Ω} (μA/sr) of a probe current extracted from an electron emission portion of a top (100) plane of the electron source at the tip of the hexaboride single crystal to a total current It (μA) emitted from the electron source can be increased to 2.6 (1/sr) to 4 (1/sr), and a current fluctuation is smaller than that in the related art (PTL 3).

### CITATION LIST

### Patent Literature

PTL 1: JP05660564
PTL 2: JP06694515
PTL 3: WO2022/064557

### SUMMARY OF INVENTION

### Technical Problem

As described above in the background art, in the field emission electron source using the hexaboride single crystal such as CeB₆, when the field emission electrons from the (100) plane serve as a probe, stability of an emission current is higher than that of field emission electrons from the {310} plane, and the stability can be further improved by increasing the ratio J_{Ω}/It of the radiation angle current density J_{Ω} (μA/sr) to the total current It (μA). As a result of further studies conducted by the inventors, it has been found that, similar to the hexaboride single crystal such as CeB₆, in a transition metal carbide single crystal such as HfC, ZrC, or TiC which is a compound having a work function lower than W and having the same cubic crystal structure, when field emission electrons from the (100) plane served as a probe, stability of emission current was also higher than that of the field emission electrons from the {310} plane. In the field emission electron source using such low work function materials, when the ratio J_{Ω}/It of the radiation angle current density J_{Ω} (μA/sr) to the total current It (μA) is increased, generation of an electron beam stimulation desorption gas can be prevented and stability is improved. Therefore, it is expected to further increase J_{Ω}/It and it is expected to develop a new technique to prevent gas adsorption to an electron emission surface.

An object of the invention is to solve the above problems and provide an electron beam device such as an electron microscope that uses a stable electron beam emitted from a local region of an electron emission surface having a desired shape that is less likely to be affected by gas adsorption and whose changes over time are stabilized, that further uses a method of preventing mixing of an unstable electron beam emitted from a region other than the emission surface, that provides a field emission electron source of a hexaboride single crystal or a transition metal carbide single crystal having both monochromaticity and long-term stability of an emission current, and that can be used for various applications requiring high resolution and long-term stability.

### Solution to Problem

In order to solve the above problems, a field emission electron source according to the invention is characterized in that a first (100) plane top facet is formed at a distal end of a tip of a hexaboride single crystal or a transition metal carbide single crystal having a <100> axis for forming the field emission electron source, the first (100) plane top facet is surrounded by side facets that include at least four {n11} planes and at least four {n10} planes, n being an integer of 1, 2, or 3, and of which a total area of {n11} plane side facets is larger than a total area of {n10} side facets, further a microcrystal having a second (100) plane top facet is formed on a plane of the first (100) plane top facet, and electrons are emitted from the second (100) plane top facet.

Here, the hexaboride single crystal is a single crystal having LaB₆ or CeB₆ as a main component, and the transition metal carbide single crystal is a single crystal having HfC, ZrC or TiC as a main component, and these single crystals are suitable materials for the invention since these single crystals have a low work function, high heat resistance and a cubic crystal structure necessary for forming the microcrystal having the second (100) plane top facet at the distal end of the tip.

The above problems can also be effectively solved by setting the second (100) plane top facet to be smaller than the first (100) plane top facet, setting a ratio of one side of the second (100) plane top facet to one side of the first (100) plane top facet in a range of 0.05 to 0.35, forming the microcrystal that forms the second (100) plane top facet into a cubic shape in which side planes are formed by a {100} plane group, or a trapezoidal shape in which side planes are formed by a {111} plane group, setting one side of the second (100) plane top facet in a range of 10 nm to 60 nm, and setting a height of the microcrystal to be 0.7 times or more a length of one side of the second (100) plane top facet.

The above problems can be effectively solved by setting one side of the first (100) plane top facet to be 1.5 μm or less and having four or less stages, so that it is possible to prevent surface diffusion of an adsorption gas from side walls of the tip toward an electron emission surface.

In order to solve the above problems, a method of producing an electron source according to the invention includes processing a distal end portion of a rod of a hexaboride single crystal or a transition metal carbide single crystal having a <100> orientation into a tip with the distal end portion of the rod being shaped into a cone shape by electrolytic polishing, and applying a high electric field with the tip having a positive polarity while heating the tip to form, at a distal end of the tip, a first (100) plane top facet surrounded by side facets that include at least four {n11} planes and at least four {n10} planes, n being an integer of 1, 2, or 3, and of which a total area of {n11} plane side facets is larger than a total area of {n10} side facets, and thereafter mainly lowering the electric field to form a microcrystal having a second (100) plane top facet on a plane of the first (100) plane top facet at the distal end of the tip.

Further, in order to solve the above problems, an electron beam device according to the invention includes an electron source, a sample stage on which a sample is placed, and an electron optical system configured to focus electrons emitted from the electron source into a beam shape and irradiate the sample on the sample stage with the focused electrons, in which a field emission electron source includes a distal end of a tip of a hexaboride single crystal or a transition metal carbide single crystal having a <100> axis, a first (100) plane top facet is formed at a distal end of the tip, the first (100) plane top facet is surrounded by side facets that include at least four {n11} planes and at least four {n10} planes, n being an integer of 1, 2, or 3, and of which a total area of {n11} plane side facets is larger than a total area of {n10} plane side facets, and further a microcrystal having a second (100) plane top facet is formed on a plane of the first (100) plane top facet.

### Advantageous Effects of Invention

According to the invention, it is possible to provide a new field emission electron source having monochromaticity and long-term stability of an emission current, and an electron beam device such as an electron microscope that includes the field emission electron source and can be used for various applications requiring high resolution and long-term stability.

### BRIEF DESCRIPTION OF DRAWINGS

FIG. 1 is an energy diagram showing an operation principle of a field emission electron source used in an electron beam device such as an electron microscope.

FIG. 2 is a perspective view showing a crystal structure (a unit lattice) of a hexaboride single crystal used in an electron source according to Embodiment 1.

FIG. 3 is a perspective view showing a crystal structure (a unit lattice) of a transition metal carbide single crystal used in the electron source according to Embodiment 1.

FIG. 4 is a schematic view showing a state in which a square pillar or a cylindrical pillar rod is cut out along a crystal axis from the hexaboride single crystal or the transition metal carbide single crystal grown on the crystal axis according to Embodiment 1.

FIG. 5 is a perspective view showing a state of mounting a stage on which a metal tube and a rod of the hexaboride single crystal or the transition metal carbide single crystal are assembled according to Embodiment 1.

FIG. 6 is a perspective view showing a positional relationship among a pressure welding tool, a stereo microscope, and the metal tube that is mounted on the state where the metal tube and the rod of the hexaboride single crystal or the transition metal carbide single crystal are assembled for illustrating a method for bonding the metal tube and the rod of the hexaboride single crystal or the transition metal carbide single crystal according to Embodiment 1.

FIGS. 7A to 7C are views showing a bonding structure of the metal tube and a square pillar rod of the hexaboride single crystal or the transition metal carbide single crystal according to Embodiment 1, in which FIG. 7A is a plan view, FIG. 7B is a perspective view, and FIG. 7C is a front cross-sectional view.

FIG. 8 is a front view showing an original structure of the electron source for illustrating an assembling structure of the electron source according to Embodiment 1.

FIGS. 9A and 9B are views showing positioning jigs used when assembling the electron source according to Embodiment 1, in which FIG. 9A is a perspective view showing the metal tube, a filament, and a positioning jig for aligning the metal tube and the filament, and FIG. 9B is a perspective view showing the metal tube to which the filament is spot-welded, a stem, and a positioning jig for aligning the metal tube and the stem.

FIGS. 10A to 10C are views showing another example of a bonding structure of the metal tube and a cylindrical pillar rod of the hexaboride single crystal or the transition metal carbide single crystal according to Embodiment 1, in which FIG. 10A is a plan view, FIG. 10B is a perspective view, and FIG. 10C is a front cross-sectional view.

FIG. 11 is a front cross-sectional view showing a state in which an electron source structure is immersed in an electrolytic polishing solution for illustrating a step of sharpening a distal end of a rod of the electron source by electrolytic polishing to form a tip according to Embodiment 1.

FIG. 12 is a front cross-sectional view showing a hexaboride tip or a transition metal carbide single crystal, and the electrolytic polishing solution for illustrating the principle of electrolytic polishing the distal end of of the rod of the electron source to form the tip according to Embodiment 1.

FIG. 13 is a front view showing the electron source of the hexaboride single crystal or the transition metal carbide single crystal according to Embodiment 1.

FIGS. 14A to 14C are diagrams showing a process of forming an electron emission surface at a distal end of a tip according to Embodiment 2 and Embodiment 3, in which FIG. 14A is a perspective view showing a shape of the distal end of the tip after electrolytic polishing, FIG. 14B is a perspective view showing a shape of the distal end of the tip after first stage thermal field processing is performed, and FIG. 14C is a perspective view showing a shape of the distal end of the tip after second stage thermal field processing is performed.

FIGS. 15A and 15B are diagrams showing process condition ranges of a producing method according to Embodiment 2, in which FIG. 15A is a diagram showing a process condition range of the first stage thermal field processing, and FIG. 15B is a diagram showing a process condition range of the second stage thermal field processing.

FIGS. 16A and 16B are cross-sectional views of a distal end of a tip showing a mechanism for forming a microcrystal having a second (100) plane top facet on a plane of a first (100) plane top facet by producing methods according to Embodiment 2 and Embodiment 3, in which FIG. 16A is a cross-sectional view showing a state of the top facet when the first stage thermal field processing is performed, and FIG. 16B is a cross-sectional view showing a state of the top facet when the second stage thermal field processing is performed.

FIGS. 17A and 17B are diagrams showing process condition ranges of a producing method according to Embodiment 3, in which FIG. 17A is a diagram showing a process condition range of the first stage thermal field processing, and FIG. 17B is a diagram showing a process condition range of the second stage thermal field processing.

FIGS. 18A and 18B show a field emission microscope observation image of a tip of transition metal carbide single crystal using HfC according to Embodiment 4, in which FIG. 18A shows a field emission microscope observation image obtained by imaging field emission of the tip after first stage heating processing, and FIG. 18B is a field emission microscope observation image obtained by imaging field emission of the tip after second stage heating processing.

FIG. 19 is a graph obtained by measuring a radiation angle current density J_{Ω} (μA/sr) relative to a total current It (μA) when only a first (100) plane top facet is formed and when a microcrystal having a second (100) plane top facet is formed in a field emission electron source of a transition metal carbide single crystal using HfC according to Embodiment 4.

FIG. 20 is a graph obtained by comparing stability of the radiation angle current density J_{Ω} (μA/sr) when only the first (100) plane top facet is formed and when the microcrystal having the second (100) plane top facet is formed in the field emission electron source of the transition metal carbide single crystal using HfC according to Embodiment 4.

FIGS. 21A to 21C are graphs showing changes in electron emission characteristics of a field emission electron source relative to a size (a length of one side) of a microcrystal having a second (100) plane top facet according to Embodiment 5, in which FIG. 21A is a graph showing a change in a field intensity at the center of a distal end of a tip, FIG. 21B is a graph showing a change in a radiation angle current density J_{Ω} (μA/sr), and FIG. 21C is a graph showing a change in a light source diameter.

FIGS. 22A and 22B are graphs showing changes in electron emission characteristics of the field emission electron source relative to a ratio of a height of the microcrystal to a length of one side of the second (100) plane top facet according to Embodiment 5, in which FIG. 22A is a graph showing a change in the field intensity at the center of the distal end of the tip, and FIG. 22B is a graph showing a change in the radiation angle current density J_{Ω} (μA/sr).

FIGS. 23A to 23C show results of studies about a relationship between a case where a length of one side of a first (100) plane top facet is 170 nm and a case where the length of one side is 340 nm according to Embodiment 5, in which FIG. 23A is a diagram showing a change in a field intensity at the center of a distal end of a tip relative to a size (a length of one side) of the microcrystal having the second (100) plane top facet, FIG. 23B is a diagram showing a change in a field intensity ratio relative to a ratio of a length of one side of the second (100) plane top facet to a length of one side of the first (100) plane top facet, and FIG. 23C is a diagram showing a change in the radiation angle current density J_{Ω} (μA/sr) relative to a ratio of the length of one side of the second (100) plane top facet to the length of one side of the first (100) plane top facet.

FIG. 24 is a perspective view showing a tip on which a first (100) plane top facet of a distal end of the tip is formed to have a multistage structure according to Embodiment 6.

FIG. 25 is a schematic cross-sectional view showing an electron beam device (a scanning electron microscope equipped with a field emission electron source using a tip of a hexaboride single crystal or a transition metal carbide according to the invention) according to Embodiment 7.

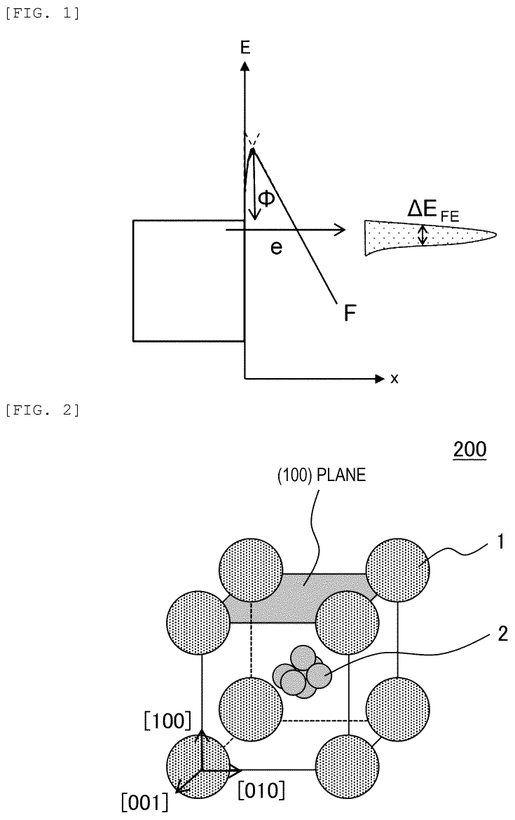

### DESCRIPTION OF EMBODIMENTS

In the following description, a crystal plane and a crystal orientation are represented according to Miller indices, a single plane is indicated by ( ) and an equivalent plane group is indicated by { }. A crystal axis direction is indicated by [ ] and an axial direction equivalent thereto is indicated by < >.

As a result of intensive studies of the inventors, according to an aspect of the invention, a field emission electron source is used in which a first (100) plane top facet is formed at a distal end of a tip of a hexaboride single crystal or a transition metal carbide single crystal having a <100> axis for forming the field emission electron source, the first (100) plane top facet is surrounded by side facets that include at least four {n11} planes and at least four {n10} planes, n being an integer of 1, 2, or 3, and of which a total area of {n11} plane side facets is larger than a total area of {n10} side facets, further a microcrystal having a second (100) plane top facet is formed on a plane of the first (100) plane top facet, and electrons are emitted from the second (100) plane top facet. A reason will be described below.

As disclosed by inventors in PTL 3, a field emission electron source using a (100) plane has higher stability of an emission current than a field emission electron source using a (310) plane, but there is a problem that a ratio of a radiation angle current density J_{Ω} (μA/sr) to a total current It (μA) is low. As a solution to this problem, it is required to reduce an amount of electrons emitted from a periphery other than the (100) plane top facet. Therefore, by developing a new producing method, a tip of an electron source was successfully produced in which a (100) plane top facet was formed at a distal end of a tip of a single crystal with a <100> axis, the (100) plane top facet was surrounded by side facets that include at least four {n11} planes and at least four {n10} planes, n being an integer of 1, 2, or 3, and of which a total area of the {n11} side facets having a high work function is larger than a total area of the {n10} side facets having a low work function, and the ratio J_{Ω}/It of the radiation angle current density J_{Ω} (μA/sr) to the total current It (μA) was increased to 2.6 to 4.

However, in this structure, a (100) plane top facet was flat, and although an area of the (100) plane top facet was reduced, {n10} planes such as {310} planes of side facets adjacent to the (100) plane top facet were sharpened, and thus an electric field was likely to be concentrated, and it was difficult to further increase J_{Ω}/It.

Therefore, by further improving a producing method disclosed in PTL 3, in an embodiment of the invention, it was found that, by forming a first (100) plane top facet surrounded by side facets that include at least four {n11} planes and at least four {n10} planes, n being an integer of 1, 2, or 3, and of which a total area of the {n11} side facets is larger than a total area of the {n10} side facets, and further forming a microcrystal having a second (100) plane top facet on a plane of the first (100) plane top facet, an electric field can be concentrated on the second (100) plane top facet, an amount of electrons emitted from the (100) plane having high stability can be increased, and an electric field applied to the {n10} planes of the side facets can be reduced relatively, so that unnecessary current emission outside an optical axis can be prevented and J_{Ω}/It can be further increased.

Hereinafter, embodiments will be described with reference to the drawings. Although a scanning electron microscope (SEM) is described as an example of an electron beam device according to the embodiments, the invention is not limited thereto. The invention can be applied to a transmission electron microscope (TEM), a scanning transmission electron microscope (STEM), an electron beam exposure device, an electron beam device including an electron beam type 3D printer, an X-ray tube, and the like. In the following drawings, a scale of each configuration is appropriately changed in order to facilitate understanding of a configuration of the invention.

### Embodiment 1

In Embodiment 1, a structure of a field emission electron source according to the invention (hereinafter, may be simply referred to as an electron source) and an assembling method of the field emission electron source will be described with reference to FIGS. 2 to 13. A method for forming first and second (100) plane top facets at a distal end of a tip, which is the feature of the invention, will be described in Embodiment 2 and subsequent embodiments.

First, a hexaboride single crystal or a transition metal carbide single crystal of rare earth is used as a material of the electron source according to the invention. Specifically, lanthanide elements such as La, Ce, Pr, Nd, Sm, Eu, and Gd can be used as the hexaboride single crystal, and are represented by chemical formulas LaB₆, CeB₆, PrB₆, NdB₆, SmB₆, EuB₆, and GdB₆, respectively. FIG. 2 is a schematic view showing a unit lattice 200. The unit lattice 200 has a cubic crystal structure in which a block of six boron atoms 2 is positioned at a body center of a simple cubic lattice of metal atoms 1. These materials generally have a high melting point (for example, LaB₆: 2483 K, CeB₆: 2463 K), low vapor pressure, high hardness, high resistance to ion bombardment, and a lower work function than W (for example, LaB₆, CeB₆: about 2.6 eV<W: about 4.3 eV), making these materials suitable as materials of an electron source. Among them, LaB₆ and CeB₆ are materials that are widely used as a material of a thermal electron source. In particular, a single crystal having LaB₆ or CeB₆ as a main component can be effectively used as the hexaboride single crystal.

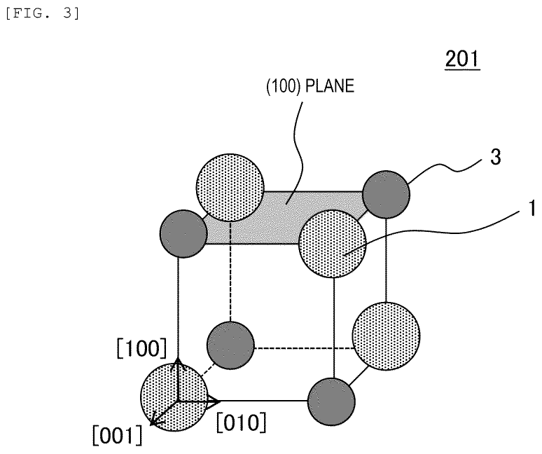

On the other hand, a single crystal having HfC, ZrC, TiC as a main component can be effectively used as the transition metal carbide single crystal. FIG. 3 is a schematic view showing a unit lattice 201. The unit lattice 201 has a cubic crystal structure in which carbon atoms 3 and the metal atoms 1 are alternately arranged. As compared with the hexaboride single crystal, these materials of the transition metal carbide single crystal have a higher melting point (for example, HfC: 4163 K, ZrC: 3805 K, TiC: 3443 K), lower vapor pressure, higher hardness, higher resistance to ion bombardment, and a lower work function than W (for example, HfC, ZrC, TiC: about 3.3 eV), making these materials suitable as materials of an electron source.

In the present embodiment, an example in which CeB₆ of the hexaboride single crystal and HfC of the transition metal carbide single crystal are used will be mainly described. Among materials of the hexaboride single crystal of rare earth, CeB₆ has f-electrons with strong energy localization and a high state density just below the Fermi level, and has a high electron density for supplying an emission current, so that CeB₆ is particularly suitable as a material of the hexaboride single crystal used to produce a field emission electron source. On the other hand, HfC is a material having a highest melting point among materials of the transition metal carbide single crystal, and HfC is particularly suitable as a material for producing a field emission electron source.

Although a producing method according to the invention is generally the same for the hexaboride single crystal and the transition metal carbide single crystal, due to differences in a melting point and reactivity with other materials constituting an electron source (especially a metal tube that holds a single crystal), there are some slight differences in a processing temperature and an assembly process of the electron source, and the differences will be described as appropriate.

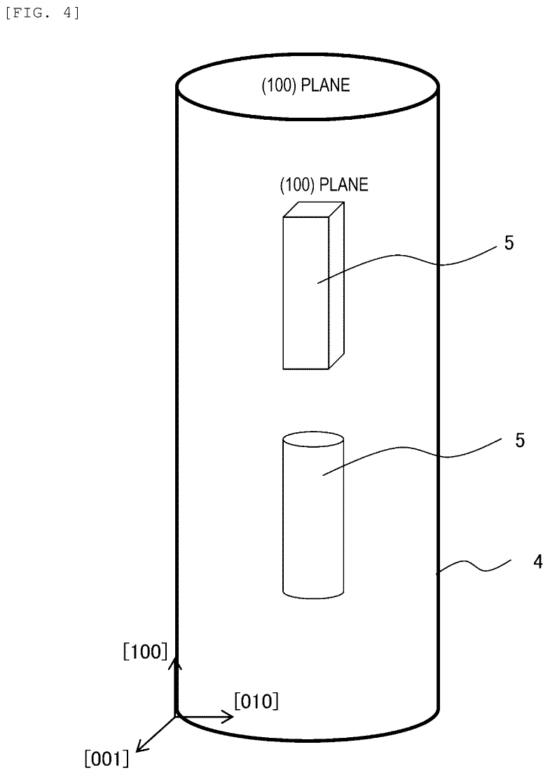

As shown in FIG. 4, the hexaboride single crystal or the transition metal carbide single crystal can be grown by melt (liquid phase) crystal growth using, for example, a floating zone method, to produce a large single crystal 4 with a diameter of several mm and a length of several mm to several tens of mm at which the crystal grows in a crystal axis direction perpendicular to a (100) plane of a crystal plane on which the crystal preferentially grows. The single crystal 4 is used by cutting out, by cutting or polishing, a rod 5 that has a length of several mm and is a square pillar having one side of 100 μm or a cylindrical pillar having a diameter of 100 μm. In the present embodiment, the rod 5 that is a square pillar having one side of 200 μm and a length of 5 mm or a cylindrical pillar having a diameter of 280 μm and a length of 5 mm was used. A longitudinal direction of the rod 5 is a orientation.

A crystal structure of the above-described hexaboride single crystal or transition metal carbide single crystal is a cubic simple cubic lattice as shown in FIGS. 2 and 3, and a (100) plane, a (010) plane, a (001) plane, a crystal axis, a crystal axis, a crystal axis, and the like are equivalent, and the effect is the same regardless of which plane or axis is used. Therefore, in the following description, an equivalent plane group is described as {100} or the like, and an equivalent axis group is described as <100> or the like.

Next, a bonding method for holding the rod 5 of the hexaboride single crystal or the transition metal carbide single crystal and attaching a filament for heating will be described with reference to FIGS. 5 to 10. In the electron source according to the present embodiment, the rod 5 of the hexaboride single crystal or the transition metal carbide is provided inside a metal tube 11 made of tantalum, niobium, or the like.

A material of the metal tube 11 used to join the rod 5 of the hexaboride single crystal or the transition metal carbide single crystal is preferably a high melting point metal such as tantalum or niobium, which is highly ductile, can be easily stretched to form the minute metal tube 11, and on which a recessed portion can be easily processed as will be described below. In the present embodiment, the minute metal tube 11 having an outer diameter Φ of 500 μm, an inner diameter Φ of 320 μm, a thickness of 90 μm, and a length of 5 mm was produced using, for example, tantalum.

Next, a method of bonding the rod 5 of the transition metal carbide single crystal or the hexaboride single crystal using the metal tube 11 will be described. First, as shown in FIG. 5, a guide pin 12 is placed vertically on a base 13, and the guide pin 12 has a diameter of 300 μm that enables the guide pin 12 to enter an inner diameter of the metal tube 11 and has a length of 1 mm to 3 mm. The guide pin 12 is inserted into the metal tube 11, and the metal tube 11 is placed p vertically on the base 13. Subsequently, when the hexaboride single crystal is used, a paste 14 is filled in the metal tube 11 from above, and the paste 14 is obtained by mixing nanoparticles such as boron tetracarbide B₄C having an average particle diameter of 0.01 μm to 0.1 μm with a carbon resin such as a furan resin. Here, nanoparticles having an average particle diameter of 0.05 μm were used. On the other hand, when the transition metal carbide single crystal is used, since the transition metal carbide single crystal does not react with the metal tube 11 made of tantalum, niobium, or the like at a high temperature, it is not necessary to perform the filling step.

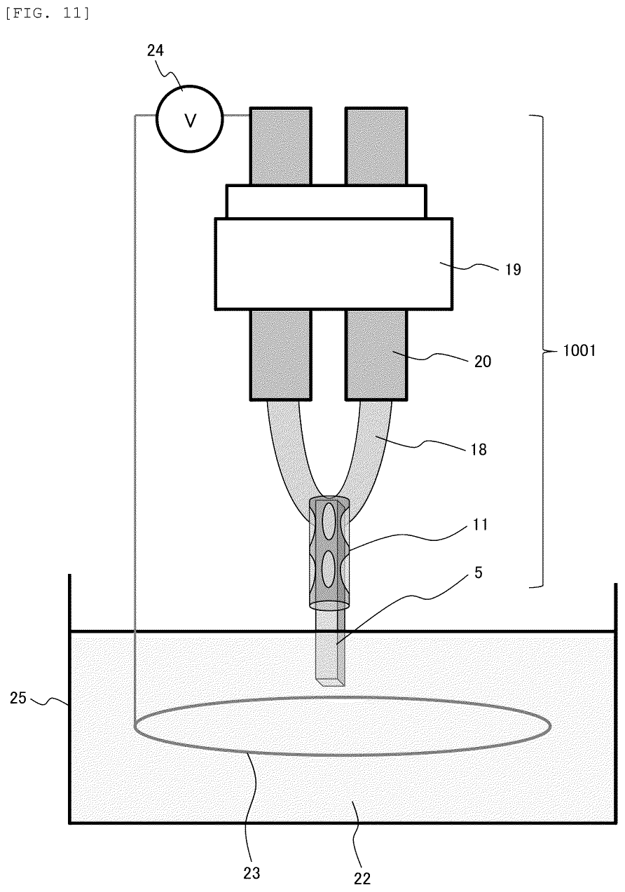

Further, the rod 5 of the hexaboride single crystal or the transition metal carbide single crystal is inserted into the metal tube 11 from above. A protruding length h at which the rod 5 of the hexaboride single crystal or the transition metal carbide single crystal protrudes from an inner side of the metal tube 11 can be controlled by the guide pin 12. In the present embodiment, in order to cut a distal end on one side of the rod 5 of the hexaboride single crystal or the transition metal carbide single crystal by electrolytic polishing, which will be described later with reference to FIGS. 11 and 12, the protruding length h is set to be 2 mm to 3 mm.

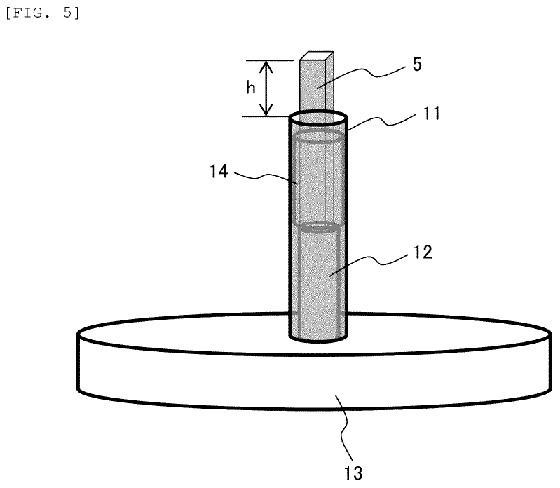

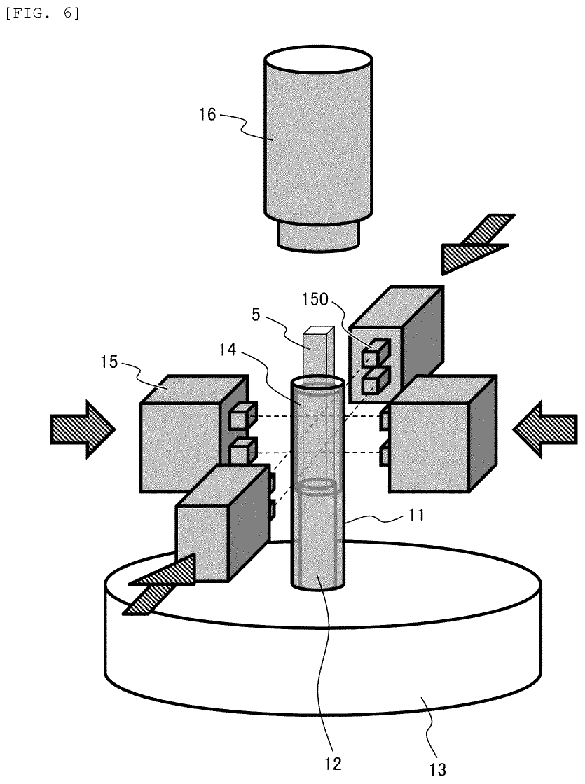

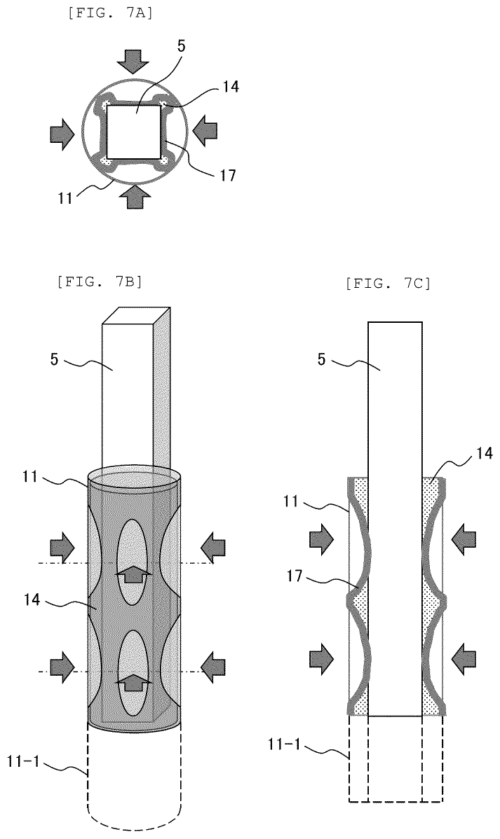

Subsequently, as shown in FIG. 6, the rod 5 of the hexaboride single crystal or the transition metal carbide single crystal and the metal tube 11 are pressure-welded to each other with a special tool developed by the inventors from two axes and four directions perpendicular to a vertical direction of the rod 5. In order to simplify description, FIG. 6 shows only blades 15 of a pressure welding tool. A pair of upper and lower protrusions 150 for forming recessed portions in the metal tube 11 are provided at a distal end of the blade 15 of the pressure welding tool. The blade 15 of the pressure welding tool is brought close to the metal tube 11 at equal strokes from the two axes and four directions, and the metal tube 11 is crushed by the protrusions 150 from an outer periphery, thereby forming a plurality of recessed portions 17 in the metal tube 11 as shown in FIG. 7C.

During an operation, a positional relationship between the metal tube 11 and the rod 5 of the hexaboride single crystal or the transition metal carbide single crystal is confirmed using a stereo microscope 16, and a rotation axis of the rod 5 of the hexaboride single crystal or the transition metal carbide single crystal is appropriately adjusted so that each side surface of the rod 5 of the square pillar hexaboride single crystal or transition metal carbide single crystal coincides with a stroke direction of the blade 15 of the tool. Accordingly, the plurality of recessed portions 17 are formed in a manner of surrounding a center axis from the outer periphery of the metal tube 11, and a bottom portion of each of the recessed portions 17 is pushed against and brought into contact with an outer peripheral surface of the rod 5 of the hexaboride single crystal or the transition metal carbide single crystal, so that the rod 5 of the hexaboride single crystal or the transition metal carbide single crystal can be fixed by being automatically aligned with the center axis of the metal tube 11.

FIGS. 7A to 7C are schematic views showing the rod 5 of the hexaboride single crystal or the transition metal carbide single crystal and the metal tube 11 that are joined by the method according to the present embodiment. FIG. 7A is a plan view showing a joint portion as viewed from a distal end side of the rod 5, FIG. 7B is a perspective view showing the rod 5, and FIG. 7C is a cross-sectional view taken along a vertical direction of the rod 5.

When the bonding method is used, the metal tube 11 and the rod 5 of the hexaboride single crystal or the transition metal carbide single crystal can be evenly pressure-welded from the two axes and four directions, and strong bonding can be obtained mechanically. In addition, since the blades 15 are brought close to the metal tube 11 at equal strokes from the two axes and four directions and the metal tube 11 is crushed from the outer periphery, the rod 5 of the square pillar hexaboride single crystal or transition metal carbide single crystal can be joined to the metal tube 11 by being automatically aligned with the center axis of the metal tube 11. Since assembly precision is improved, it is easier to align an axis of the electron source, yield is also improved. Further, since the rod 5 can be joined at upper and lower two positions in an axial direction, the rod 5 can be prevented from being inclined at a joint portion, and accuracy of an axial alignment can be further increased.

Further, when the hexaboride single crystal is used, the paste 14 obtained by mixing nanoparticles of boron tetracarbide BAC with a carbon resin such as a furan resin is flexibly deformed at the time of pressure welding, and a space between the deformed metal tube 11 and the rod 5 of the hexaboride single crystal is filled without a gap. Since small nanoparticles having an average particle diameter of 0.1 μm or less are used as the paste 14, the rod 5 of the hexaboride single crystal is not damaged or broken at the time of pressure welding, and yield in a pressure welding step can be improved. The reason why the average particle diameter of the nanoparticles is set to be 0.01 μm or more is that when the average particle diameter is too small, an apparent volume of B₄C powder increases, mixing for the paste becomes difficult, production of the nanoparticles becomes difficult, and cost increases.

After the metal tube 11 is pressure-weld to the rod 5 of the hexaboride single crystal or the transition metal carbide single crystal, a portion 11-1 indicated by a dotted line of the metal tube 11 into which the guide pin 12 is inserted is not necessary, and thus, after the metal tube 11 is removed from the guide pin 12, the portion 11-1 is cut out with a cutter to reduce heat capacity of the metal tube 11. Thereafter, in the case of the hexaboride single crystal, the paste 14 is heated in the air to become harden, and then heated at a high temperature of 1000° C. or higher in a vacuum for several hours to carbonize the paste 14. Accordingly, degassing from the paste 14 is eliminated, and a reaction barrier layer for preventing reaction at high temperature between the metal tube 11 made of tantalum or the like and the rod 5 of the hexaboride single crystal can be formed.

Subsequently, as shown in FIG. 8, a filament 18 made of tungsten or the like is directly spot-welded to the metal tube 11 to which the rod 5 of the hexaboride single crystal or the transition metal carbide single crystal is joined. Further, both ends of the filament 18 are spot-welded to a pair of electrodes 20 fixed to a stem 19 to form a structure 1001 which is a prototype of an electron source. Since the structure 1001 is formed by bonding metals, strong bonding can be obtained by spot welding.

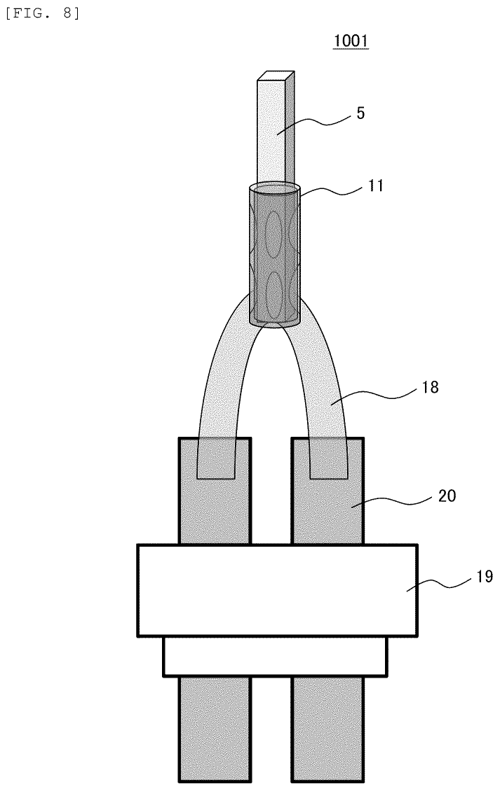

A specific example of welding processing for forming the structure 1001 will be described with reference to FIGS. 9A and 9B. When the filament 18 made of tungsten or the like is directly spot-welded to the metal tube 11 to which the rod 5 of the hexaboride single crystal or the transition metal carbide single crystal is joined, a positioning jig 21 as shown in FIG. 9A is used. First, the filament 18 made of tungsten or the like is accurately aligned with the metal tube 11 using a positioning jig 21-1, and the metal tube 11 and the filament 18 are spot-welded.

Subsequently, as shown in FIG. 9B, the metal tube 11 to which the filament 18 is spot-welded and the stem 19 are accurately aligned by using a positioning jig 21-2, and the filament 18 and the pair of electrodes 20 fixed to the stem 19 are spot-welded to form the structure 1001. As described above, by using the positioning jigs 21-1 and 21-2, since a center axis of the metal tube 11, a center axis of the rod 5 of the hexaboride single crystal or the transition metal carbide single crystal are aligned with the center of the pair of electrodes 20 fixed to the stem 19 in a stage when the rod 5 and the stem 19 are assembled as the structure 1001, the structure 1001 allows for highly accurate centering.

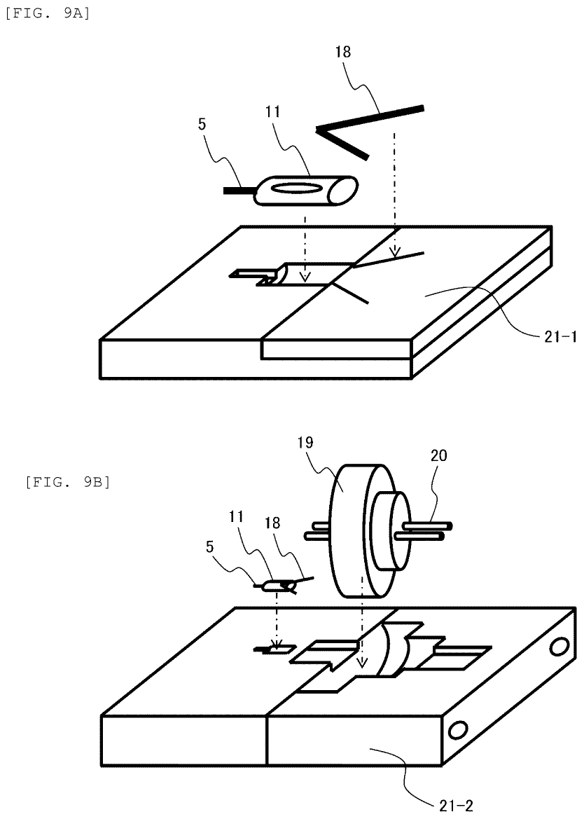

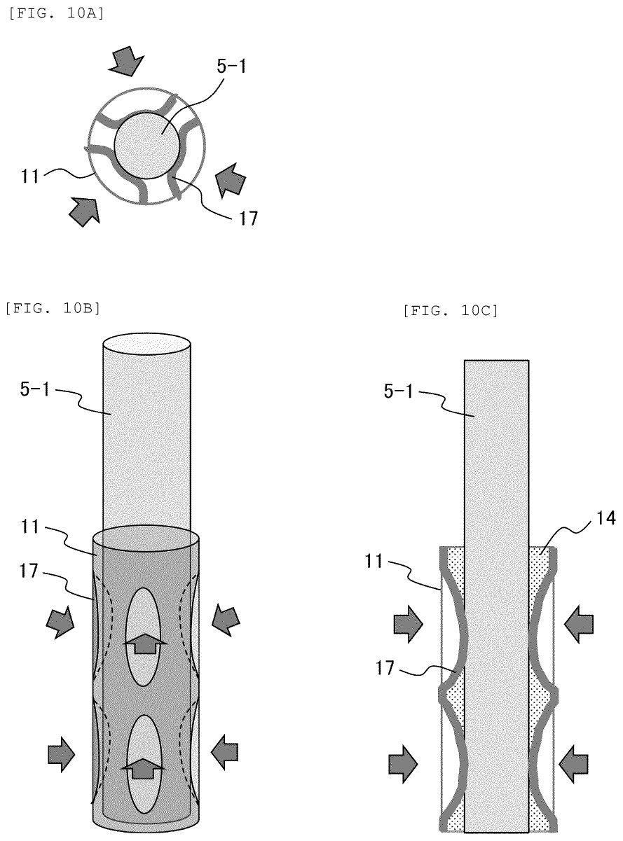

In the embodiment described above, the rod 5 of the hexaboride single crystal or the transition metal carbide single crystal that is cut into a square pillar shape is used as a structural component of the structure 1001. The rod 5 of the hexaboride single crystal or the transition metal carbide single crystal may be processed into a cylindrical pillar as shown in FIG. 4. FIGS. 10A-10C show an example when a rod 5-1 of a cylindrical pillar hexaboride single crystal or transition metal carbide single crystal is used. In a case where the rod 5-1 of the cylindrical pillar hexaboride single crystal or transition metal carbide single crystal is joined to the metal tube 11, it is sufficient that the rod 5-1 and the metal tube 11 are pressure-welded using a special tool developed in the present embodiment from three axes and three directions at equal intervals in a plane perpendicular to the vertical direction of the rod 5-1 of the hexaboride single crystal or the transition metal carbide single crystal. In particular, in the case of the rod 5 of the transition metal carbide single crystal, since the rod 5 can be pressure-welded without using the paste 14, it is preferable to process the rod 5 into a cylindrical pillar having a similar shape to the inner diameter of the metal tube 11, which makes pressure welding easier.

FIG. 10A is a plan view showing a joint portion as viewed from a distal end side of the rod 5-1, FIG. 10B is a perspective view showing the rod 5-1, and FIG. 10C is a cross-sectional view taken along a vertical direction of the rod 5-1. FIGS. 10B and 10C show a state after cutting a portion corresponding to the portion 11-1 that is unnecessary after the rod 5 of the hexaboride single crystal or the transition metal carbide single crystal is pressure-welded to the metal tube 11 as described with reference to FIG. 6.

It is needless to say that the metal tube 11 and the rod 5-1 of the cylindrical pillar hexaboride single crystal or transition metal carbide single crystal may be joined by being pressure-welded to each other from two axes and four directions in a similar manner to the case of the rod 5 of the square pillar hexaboride single crystal or transition metal carbide single crystal as described with reference to FIG. 6 and FIGS. 7A to 7C.

Subsequently, in the structure 1001, a distal end of a portion of the rod 5 of the hexaboride single crystal or the transition metal carbide single crystal where the rod 5 protrudes out from the metal tube 11 is reduced in diameter in a cone shape by electrolytic polishing. The electrolytic polishing is performed by dipping a distal end portion of the rod 5 of the hexaboride single crystal or the transition metal carbide single crystal that is assembled as shown in FIG. 11 in an electrolytic solution 22 such as nitric acid in a container 25, and applying a voltage from a power supply 24 of an alternating current or a direct current to a space between the power supply 24 and a ring-shaped counter electrode 23 made of platinum or the like.

As shown in FIG. 12, when the rod 5 of the hexaboride single crystal or the transition metal carbide single crystal is immersed in the electrolytic solution (an electrolytic polishing solution) 22, a meniscus is formed on a liquid surface, and a polishing speed of a liquid surface portion is slow and a polishing speed of an in-liquid portion is fast. As the electrolytic polishing progresses and a polishing area of a portion of the rod 5 of the hexaboride single crystal or the transition metal carbide single crystal where the rod 5 is immersed in the electrolytic solution 22 is reduced, an electrolytic current is attenuated. In a case where the power supply 24 is cut off when a field current is attenuated to a constant level (a cutoff current), the distal end portion can be processed into a tapered tip 6 as indicated by dotted lines in FIG. 12. The tip 6 has a longitudinal direction of the orientation.

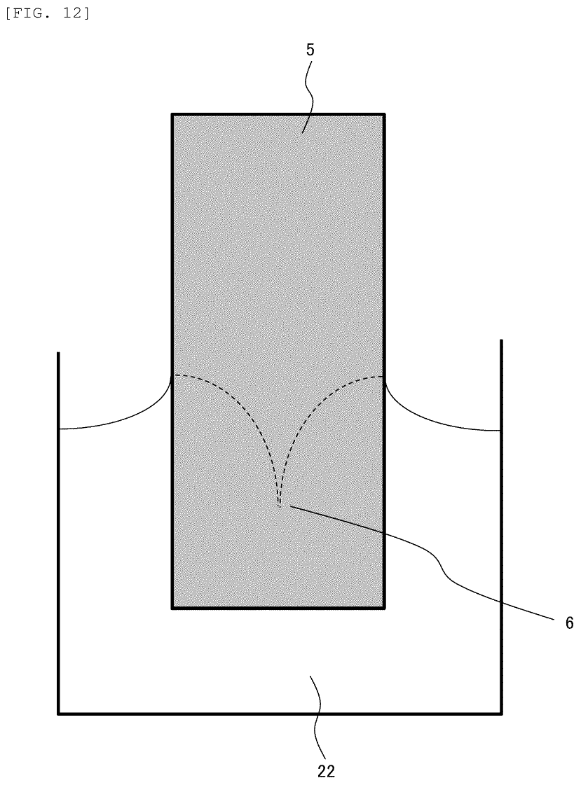

The assembly of the electron source is completed through the above steps. FIG. 13 shows a structure of a field emission electron source 100. The rod 5 of the hexaboride single crystal or the transition metal carbide single crystal that has the tip 6 reduced in diameter by electrolytic polishing is held in the metal tube 11. The metal tube 11 is welded to the filament 18 and further welded to the electrode 20 of the stem 19. A plurality of recessed portions are provided on the outer periphery of the metal tube from at least two axial directions in a manner of surrounding the center axis, and a bottom portion of each of the plurality of recessed portions is brought into contact with an outer periphery of the rod 5 of the hexaboride single crystal or the transition metal carbide single crystal provided inside the metal tube. Accordingly, strong and reliable bonding can be performed in which the rod 5 of the hexaboride single crystal or the transition metal carbide single crystal does not fall off even when the rod 5 is heated at a high temperature. When the hexaboride single crystal is used, since the hexaboride single crystal reacts with the metal tube 11 made of tantalum, niobium, or the like at a high temperature, the paste 14 that is a mixture of nanoparticles of boron tetracarbide having an average particle diameter of 0.01 μm to 0.1 μm with a carbon resin was filled between the metal tube 11 and the rod 5 of the hexaboride single crystal, and the paste 14 was cured and further carbonized to perform bonding with high heat resistance. On the other hand, when the transition metal carbide single crystal is used, since the transition metal carbide single crystal does not react with the metal tube 11 made of tantalum, niobium, or the like at a high temperature, the present step was not performed.

### Embodiment 2

In Embodiment 2, a process of forming an electron emission surface according to the invention on the tip 6 at a distal end of the field emission electron source 100 of the hexaboride single crystal produced in Embodiment 1 will be described. The field emission electron source 100 of the transition metal carbide will be described in Embodiment 3.

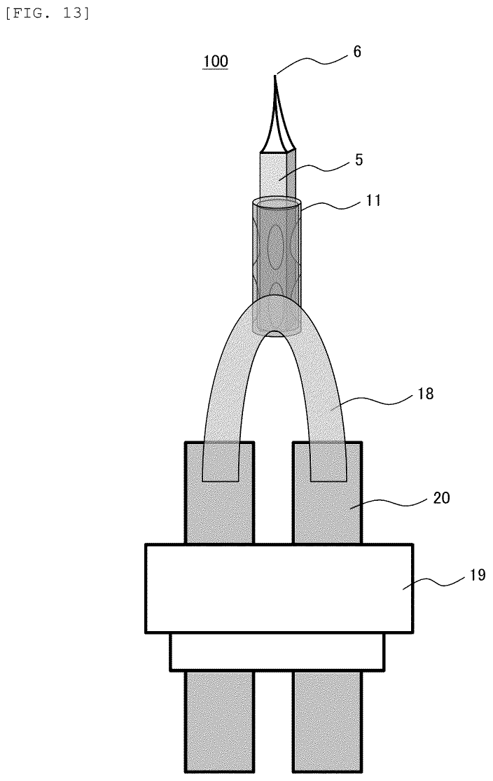

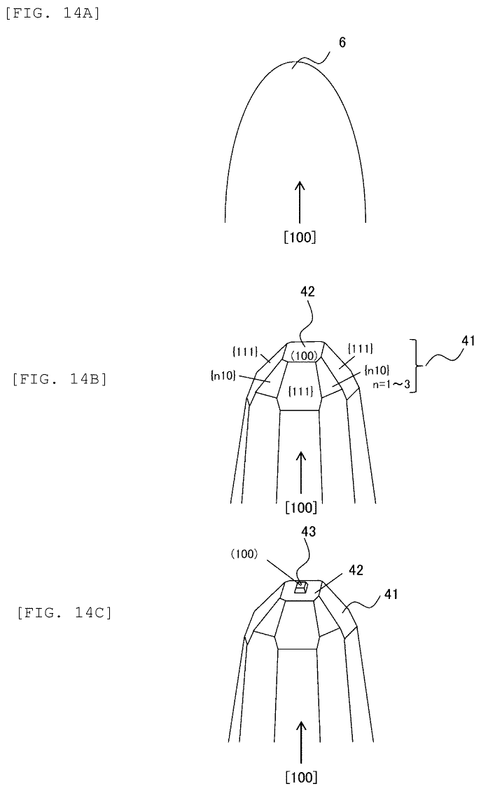

FIGS. 14A-14C are views showing a process of forming the electron emission surface at a distal end of the tip according to Embodiment 2 and Embodiment 3. FIG. 14A is a perspective view showing a shape of the distal end of the tip after electrolytic polishing, FIG. 14B is a perspective view showing a shape of the distal end of the tip after first stage thermal field processing is performed, and FIG. 14C is a perspective view showing a shape of the distal end of the tip after second stage thermal field processing is performed. FIGS. 15A and 15B are diagrams showing process condition ranges of a producing method according to Embodiment 2, in which FIG. 15A is a diagram showing a process condition range of the first stage thermal field processing, and FIG. 15B is a diagram showing a process condition range of the second stage thermal field processing.

First, in the first stage processing, the field emission electron source 100 of the hexaboride single crystal whose longitudinal direction is the orientation, in which the tip 6 is formed at a distal end by electrolytic polishing the distal end shown in FIG. 14A, is set in a vacuum chamber (not shown), and as shown in FIG. 14B, a first (100) plane top facet 42 is formed at the tip 6 of the hexaboride single crystal having the <100> axis, and the first (100) plane top facet 42 is surrounded by side facets 41 that include at least four {n11} planes and at least four {n10} planes, n being an integer number of 1, 2, or 3, and of which a total area of the {n11} plane side facets is larger than a total area of the {n10} plane side facets. Since the {n11} planes of the hexaboride single crystal have a higher work function than the {n10} planes, it is possible to reduce unnecessary current emitted to the outside of an optical axis from the side facets 41 by setting the total area of the {n11} plane side facets to be larger than the total area of the {n10} plane side facets.

A characteristic of this producing method is that, as shown in a process region 151 in FIG. 15A, thermal field processing is performed in which an electric field of 1×10⁹ V/m to 4.5×10⁹ V/m with the tip 6 having a positive polarity is applied while heating the tip 6 at 1500° C. to 1700° C. in a vacuum. Hereinafter, effects of the heating and the electric field application in the first stage thermal field processing will be specifically described with reference to FIG. 15A.

First, effects of the heating in the first stage thermal field processing will be described. The rod 5 of the hexaboride single crystal is made of a material having a high melting point (LaB₆: 2210° C., CeB₆: 2190° C.). When the rod 5 is heated at 700° C. to 1400° C. in a vacuum, a crystal plane of the tip 6 at the distal end is reconstructed due to atomic migration on a surface, as shown in a process region 152. In this case, there is a tendency that the (100) plane grows on a top portion of the tip 6 and {n10} planes and {n11} planes grow on side portions of the tip 6 in a manner in which {n10} planes> {n11} planes. Further, when the rod 5 is heated at 1500° C. or higher as in a process region 153, evaporation from a surface gradually progresses, a crystal structure of the surface collapses, and the evaporation becomes more significant at 1700° C. or more in a process region 154.

Therefore, heating at 1500° C. to 1700° C. mainly plays the role of causing evaporation, and when an electric field is not applied to the tip 6 of the hexaboride single crystal, or when the rod 5 is heated while being applied with a low electric field of 1×10⁹ V/m or less, the tip 6 is thinned while maintaining a similar shape to the shape formed by electrolytic polishing as in the process region 153. Further, when the rod 5 is heated at 1700° C. or higher as in the region 154, the evaporation becomes intense, and it is difficult to maintain a similar shape to the shape formed by electrolytic polishing.

Next, effects of the electric field applied to the tip 6 in the first stage thermal field processing will be described. There are two kinds of effects. First, a first effect will be described below.

In the present embodiment, as described above, evaporation on the surface of the tip 6 occurs only when the tip 6 is heated at 1500° C. to 1700° C. in the process region 153, and further field evaporation also occurs when an electric field with the tip 6 having a positive polarity is applied to the tip 6. Different from evaporation due to heating, a characteristic of the field evaporation is that a sharp portion of the tip 6 evaporates preferentially, so that the distal end of the tip 6 is processed to have a shape close to a hemisphere as a whole.

Next, a second effect will be described. In general, it is known that when a high electric field is applied to the tip 6 that is heated, atomic diffusion occurs on a surface due to electrostatic force, a crystal plane with a high atomic density grows large and builds up, as in the case of a ZrO/W (100) tip of a Schottky electron source.

As a result of intensive studies, the inventors have found that, even in the case of the tip of the hexaboride single crystal with a <100> axis, when a high electric field of 1×10⁹ V/m to 4.5×10⁹ V/m is applied to the tip 6 that is heated to 1500° C. to 1700° C. as in the process region 151, building up in which the (100) plane is formed at a top portion of the tip 6 occurs. Further, it has been found that an electric field causing building up does not have polarity dependency, and it is possible to build up the (100) plane using either an electric field with a positive polarity or an electric field with a negative polarity.

However, when an electric field with a negative polarity is applied to the tip, since there is no effect of the above-described field evaporation, and a large amount of electrons are emitted from the tip of the hexaboride single crystal that is heated at a high temperature and is applied with a high electric field, there is a risk that a vacuum level is lowered due to generation of an electron beam stimulation desorption gas and the tip is damaged due to discharge. Therefore, it is preferable that the electric field applied in the producing method according to the present embodiment has a positive polarity.

When an electric field higher than 4.5×10⁹ V/m is applied as in a process region 155, the effect of field evaporation becomes too strong, and the distal end of the tip 6 is processed into a hemispherical shape.

In the first stage thermal field processing (the process region 151) according to the present embodiment, by appropriately combining the effect of the thermal field evaporation and the effect of building up, it is possible to form the first (100) plane top facet 42 at the tip 6 of the distal end of the hexaboride single crystal with a <100> axis, and the first (100) plane top facet 42 is surrounded by the side facets 41 that include at least four {n11} planes and at least four {n10} planes, n being an integer of 1, 2, or 3, and of which a total area of the {n11} plane side facets is larger than a total area of the {n10} plane side facets. This is because, due to the effect of the thermal field evaporation, a sharp portion of the tip 6 is cut off and is less likely to grow as compared with a curvature of the entire surface of the tip 6 such as the {n10} plane, and due to the building up effect, growth of the (100) plane at the top portion of the tip 6 and growth, at side portions, of the {n11} planes surrounding the (100) plane, especially the {111} crystal planes having a high density, are facilitated. This is the effect of the first stage thermal field processing according to the invention.

According to the invention, subsequent to the first stage thermal field processing, new second stage thermal field processing is performed to form a microcrystal having a second (100) plane top facet 43 on a plane of the (100) plane top facet 42, as shown in FIG. 14C. Here, the microcrystal that is formed as the second (100) plane top facet has a cubic shape in which side surfaces are formed by a {100} plane group, or the side surfaces is formed in a trapezoidal shape by a {111} plane group.

Specifically, as shown in the process region 156 in FIG. 15B, after the first (100) plane top facet 42 was formed by the first stage thermal field processing, a heating temperature was lowered to 1300° C. to 1500° C., and an electric field with a positive polarity was lowered to 1×10⁹ V/m to 2.25×10⁹ V/m, which was a half or less. The reason why the heating temperature is lowered to 1300° C. to 1500° C. is to prevent evaporation of CeB₆, and the electric field is lowered to less than a half to weaken the building up effect.

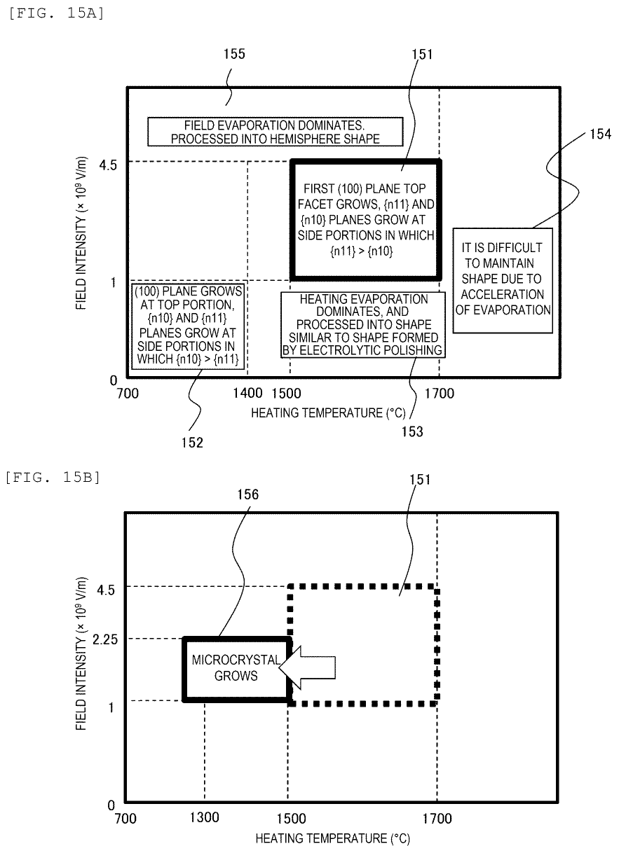

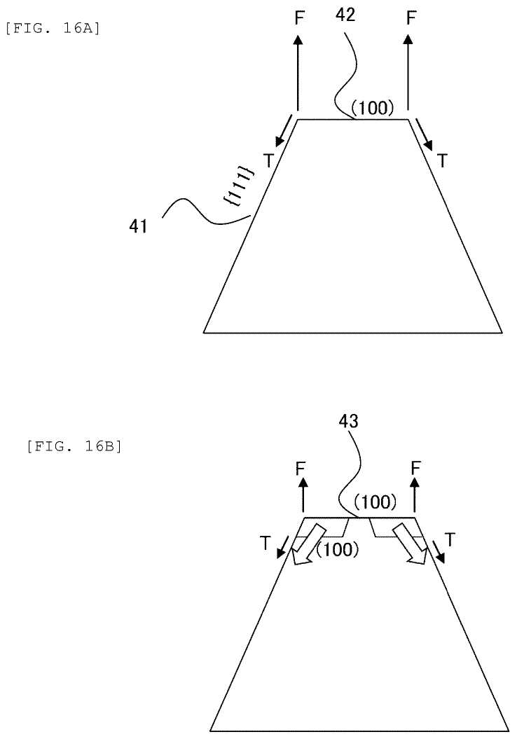

FIGS. 16A and 16B are cross-sectional views showing a structural change occurring in an end surface of the first (100) plane top facet 42 at the tip 6 in the first stage thermal field processing shown in FIG. 15A and the second stage thermal field processing shown in FIG. 15B. The building up occurs because an atomic diffusion amount toward the distal end of the tip 6 due to an electrostatic force of an electric field F exceeds an atomic diffusion amount toward a lower side of the tip 6 at a temperature T as shown in FIG. 16A, the atomic diffusion toward a top portion of the tip 6 is facilitated, and growth of the (100) plane at the top portion and growth of the side facets 41, especially {111} plane crystal planes having a high density, at side portions surrounding the (100) plane are facilitated. When the electric field F is lowered as in the second stage thermal field processing shown in FIG. 15B from this state, the atomic diffusion amount on the surface toward the distal end of the tip 6 decreases. At this time, when an atomic diffusion amount on the surface of the tip 6 toward a lower side at the temperature T is larger, the end surface of the first (100) plane facet 42 at the top portion of the tip 6 collapses as shown in FIG. 16B, a step is generated on the (100) plane, and a microcrystal having the second (100) plane top facet 43 is formed on the plane of the first top facet 42. In the present embodiment, the temperature is lowered in order to prevent evaporation of CeB₆, but when the temperature T is lowered to much, the atomic diffusion amount on the surface of the tip 6 toward the lower side also decreases, and therefore it is not preferable to lower the temperature to 1300° C. or lower.

That is, a producing method of the field emission electron source 100 can be summarized as follows. A high electric field with the tip 6 having a positive polarity is applied, at a high temperature, to the tip 6 of a hexaboride single crystal or a transition metal carbide single crystal whose longitudinal direction is the orientation, thereby causing building up due to movement of atoms toward the distal end of the tip 6 to form the first (100) plane top facet 42. Thereafter, by lowering the electric field applied to the tip 6, the microcrystal having the second (100) plane top facet 43 grows on the plane of the first (100) plane top facet 42.

Although the invention is applied to an example of CeB₆ in the present embodiment, the same process can be applied to LaB₆ having substantially the same thermal characteristics such as a melting point and the same chemical properties.

By performing the above-described two stages thermal field processing, the first (100) plane top facet 42 can be formed at the tip 6 of the hexaboride single crystal having the <100> axis, such as CeB₆ and LaB₆, which has a longitudinal direction of the [100] orientation, the first (100) plane top facet 42 is surrounded by side facets that include at least four {n11} planes and at least four {n10} planes, n being an integer of 1, 2, or 3, and of which a total area of the {n11} plane side facets is larger than a total area of the {n10} side facets, and further the microcrystal having the second (100) plane top facet 43 can be formed on a plane of the first (100) plane top facet 42.

### Embodiment 3

Next, a process of forming an electron emission surface at a distal end of a tip of a transition metal carbide single crystal such as HfC, ZrC, and TiC will be described with reference to FIGS. 14, 16, and 17 in the present embodiment. Since the transition metal carbide single crystal has a melting point that is significantly higher than that of the hexaboride single crystal (HfC: 3890° C., ZrC: 3532° C., TiC: 3170° C., LaB₆: 2210° C., CeB₆: 2190° C.), and has very low vapor pressure, although a process temperature and an evaporation effect are different from those in the Embodiment 1, a basic process concept is the same.

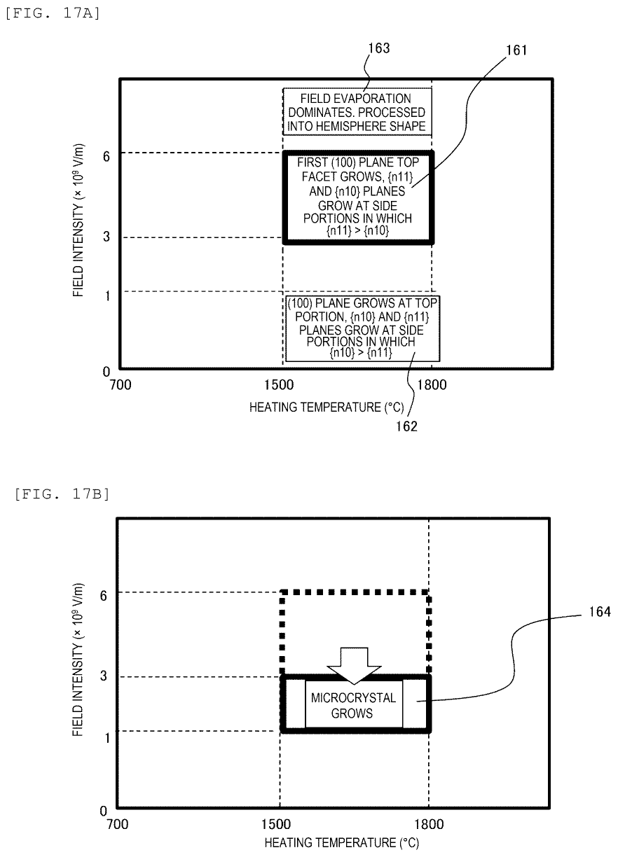

FIGS. 17A and 17B are diagrams showing process condition ranges of a producing method according to Embodiment 3, in which FIG. 17A shows a process condition range of first stage thermal field processing, and FIG. 17B shows a process condition range of second stage thermal field processing.

First, in the first stage thermal field processing, as in the case of the hexaboride single crystal, the field emission electron source 100 of the transition metal carbide single crystal, in which the tip 6 is formed at a distal end by electrolytic polishing the distal end shown in FIG. 14A, is set in a vacuum chamber (not shown), and an electric field of 3×10⁹ V/m to 6×10⁹ V/m with the tip 6 having a positive polarity is applied while heating the tip 6 at 1500° C. to 1800° C. in a vacuum as shown in a process region 161 shown in FIG. 17A. Accordingly, the first (100) plane top facet 42 is formed at a tip 40 of the transition metal carbide with the <100> axis, and the first (100) plane top facet 42 is surrounded by the side facets 41 that include at least four {n11} planes and at least four {n10} planes, n being an integer of 1, 2, or 3, and of which a total area of the {n11} plane side facets is larger than a total area of the {n10} side facets. Since the {n11} planes of the transition metal carbide single crystal also have a work function higher than the {n10} planes, it is possible to reduce an unnecessary current emitted to the outside of an optical axis from the side facets 41 by setting the total area of the {n11} plane side facets to be larger than the total area of the {n10} plane side facets.

As shown in a process region 162, when the tip 6 is heated to 1500° C. to 1800° C. in a vacuum, a crystal plane of the tip 6 at the distal end is more likely to be reconstructed due to an atomic movement on a surface. In this case, there is a tendency that the (100) plane grows on a top portion of the tip 6 and {n10} planes and {n11} planes grow on side portions of the tip 6 in a manner of {n10} planes> {n11} planes. As shown in a process region 163, when the tip 6 is heated to 1500° C. to 1800° C. in a vacuum and an electric field higher than 6×10⁹ V/m is applied, the effect of the field evaporation becomes too strong, and a distal end of the tip 6 is processed into a hemispherical shape.

The reason why a distal end structure of the tip 6 is the same as that in the case of the hexaboride single crystal is that the transition metal single crystal is a compound having the same cubic crystal structure as that of the hexaboride single crystal, and the transition metal single crystal has a geometric relationship between the side facets 41 and the top facet 42 in which surface energy at the time of building up is stable similar to that in the case of the hexaboride single crystal. However, it is necessary to reflect a difference in a melting point and the like, and apply a higher temperature and a higher electric field than those applied to the tip of the hexaboride single crystal.

Subsequently, in the second stage thermal field processing, an electric field with a positive polarity was lowered to 1×10⁹ V/m to 3×10⁹ V/m, which is a half or less, while heating the tip 6 at 1500° C. to 1800° C. as shown in a process region 164 in FIG. 17B in the present embodiment. Accordingly, an atomic diffusion amount toward a lower side of the tip 6 at the temperature T is larger than an atomic diffusion amount on the surface toward the distal end of the tip 6 due to the electrostatic force of the electric field F, the end surface of the first (100) plane top facet 42 collapses, a step is generated on the (100) plane, and a microcrystal having the second (100) plane top facet 43 is formed on the plane of the first top facet 42.

### Embodiment 4

In the present embodiment, electron emission characteristics of a field emission electron source produced according to the invention will be described. Here, an example will be described with a field emission electron source using HfC of a transition metal carbide single crystal in which the first (100) plane top facet 42 has a regular square shape with a length of 170 nm×a width of 170 nm and a size of the microcrystal constituting the second (100) plane top facet 43 has a cube shape with a length of 50 nm×a width of 50 nm×a height of 50 nm.

Although not described in the present embodiment, in the case of using a field emission electron source of another transition metal carbide single crystal such as ZrC, or in the case of a field emission electron source using a hexaboride single crystal such as CeB₆, almost the same characteristics can be obtained with a slight difference.

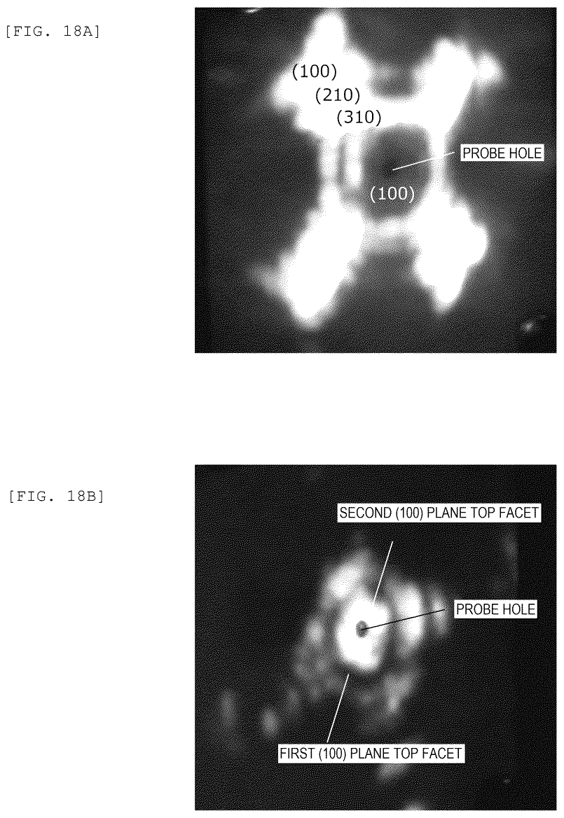

First, FIG. 18A shows a field emission microscope (FEM) image of a field emission electron source of HEC produced in steps up to the first thermal field processing shown in (FIG. 17A, and FIG. 18B shows an FEM image of a field emission electron source of HfC produced in steps up to the second thermal field processing shown in FIG. 17B.

As shown in the FEM image in FIG. 18A, for the tip 6 produced in steps up to the first thermal field processing in FIG. 17A, the first (100) plane top facet 42 of the tip 6 has a large area and is flat, so that it is difficult to apply an electric field to the tip 6, and an amount of an emission current is relatively small, and the first (100) plane top facet 42 is dark. On the other hand, the {n10} facets (n=1 to 3) such as surrounding {310} planes, {210} planes, and {110} planes are sharped, and an electric field tends to be concentrated, so that an amount of an emission current is relatively large, and the {n10} facets are bright.

On the other hand, as shown in the FEM image in FIG. 18B, for the tip produced in steps up to the second thermal field processing in FIG. 17B, an electric field is concentrated on the second (100) plane top facet 43 formed by a microcrystal formed on the plane of the first (100) plane top facet 42, so that the center of the tip is relatively bright. On the other hand, on the first (100) plane top facet 42 serving as a base and the side facets of the {n10} planes surrounding the first (100) plane top facet 42, a field intensity is relatively lowered, the first (100) plane top facet 42 and the side facets are dark.

FIG. 19 shows the radiation angle current density J_{Ω} (μA/sr) per the total current It (μA) obtained by comparing the tip 6 formed with only the first (100) plane facet 42 shown in FIG. 18A and the tip 6 formed with the microcrystal having the second (100) plane facet 43 according to the invention shown in FIG. 18B. A line 1900 indicates the radiation angle current density J_{Ω} (μA/sr) per the total current It (μA) of the tip 6 of the field emission electron source formed with only the first (100) plane facet 42. A line 1901 indicates the radiation angle current density J_{Ω} (μA/sr) per the total current It (μA) of the tip 6 of the field emission electron source formed with the microcrystal having the second (100) plane facet 43. For the tip 6 according to the invention, as indicated by the line 1901, J_{Ω}/It is increased by about four times of 12 or more, and a large radiation angle current density J_{Ω} (μA/sr) is obtained with a small total current It (μA).

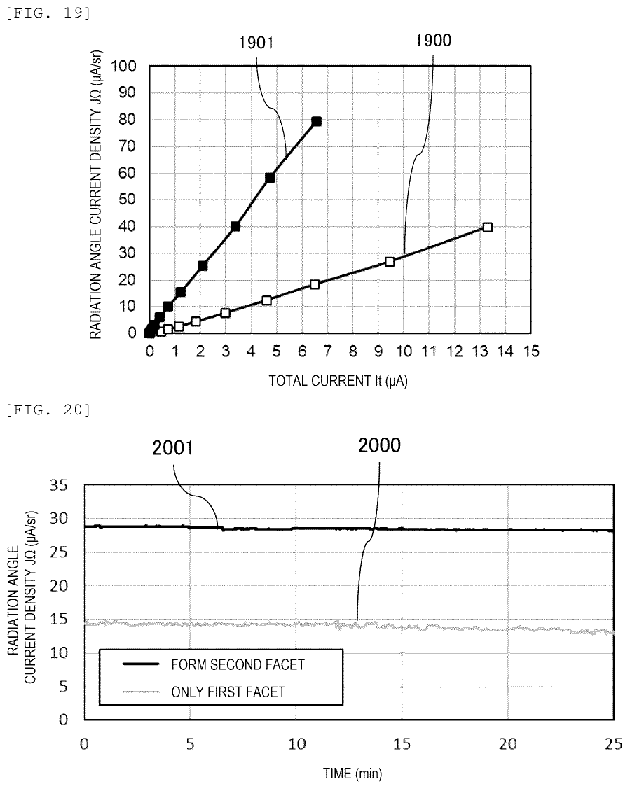

FIG. 20 shows a result obtained by comparing stability of the radiation angle current density J_{Ω} (μA/sr) between the field emission electron source formed with only the first (100) plane top facet 42 shown in FIG. 18A and the field emission electron source formed with the microcrystal having the second (100) plane top facet 43 according to the invention shown in FIG. 18B. A line 2000 indicates the radiation angle current density J_{Ω} (μA/sr) of the tip 6 of the field emission electron source formed with only the first (100) plane top facet 42, and a line 2001 indicates the radiation angle current density J_{Ω} (μA/sr) of the field emission electron source formed with the microcrystal having the second (100) plane top facet 43.

An initial value of J_{Ω} (μA/sr) of the tip formed with only the first (100) plane top facet 42 was set to 14 μA/sr, and an initial value of J_{Ω} (μA/sr) of the field emission electron source formed with the microcrystal having the second (100) plane top facet 43 was set to 28 μA/sr. In the field emission electron source formed with only the first (100) plane top facet 42, as indicated by the line 2000, there are noises in an emission current, the noises increase over time, and the emission current is reduced. On the other hand, as indicated by the line 2001, even though the initial value of J_{Ω} (μA/sr) of the field emission electron source formed with the microcrystal having the second (100) plane top facet 43 is set to be twice, there is almost no current noises, and the current is stable without any reduction.

A first reason is that, J_{Ω}/It of the field emission electron source formed with the microcrystal having the second (100) plane top facet 43 is four times that of the field emission electron source formed with only the first (100) plane top facet 42, so that even with twice J_{Ω} (μA/sr), the total current It (μA) is reduced by half, and the electron beam stimulation desorption gas generated from an electrode is reduced by half. As a result, the electron beam stimulation desorption gas that is incident on the second (100) plane top facet 43 is reduced by half.

However, this alone cannot explain a large difference in stability. A second reason is that a step of the microcrystal that forms the second (100) plane top facet 43 becomes a diffusion barrier when a gas adsorbed on a side wall of the tip 6 surface-diffuses toward the top portion of the tip 6, or becomes a trap site of the adsorbed gas, and the adsorbed gas is less likely to reach the second (100) plane top facet 43.

As described above, when the field emission electron source according to the invention is used, J_{Ω}/It>12 (1/sr) can be obtained, which is four times or more a field emission electron source in the related art, and the radiation angle current density J_{Ω} (μA/sr) required for an electron microscope can be obtained with a small total current It (μA). Specifically, it is possible to obtain J_{Ω} (μA/sr) of 10 μA/sr to 25 μA/sr which is generally required in an electron microscope with a very small total current It (μA) of 0.7 μA to 2 μA. In addition, under a condition of a general total current It of 10 μA in an ordinary electron microscope, a large radiation angle current density J_{Ω} (μA/sr) of 100 μA/sr or more can be obtained, and for example, it is possible to cope with a high speed such as in an elemental analysis requiring a large radiation angle current density.

### Embodiment 5

A size of the microcrystal (here, defined by a length of one side of the (100) plane facet of the microcrystal) can be controlled by an electric field, a temperature, and a maintaining time applied in the second thermal field processing in Embodiment 2 and Embodiment 3. Here, in the present embodiment, a change in electron emission characteristics depending on the size of the microcrystal formed on the plane of the first (100) plane top facet 42 is studied, and a result obtained by obtaining an optimum size of the microcrystal, a height, a relationship between a size of the first (100) plane top facet 42 and a size of the second (100) plane top facet 43, and the like will be described.

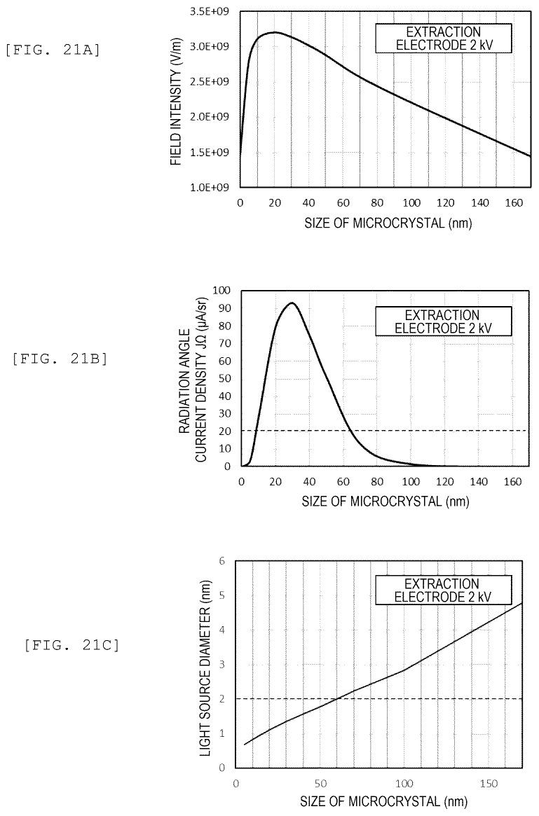

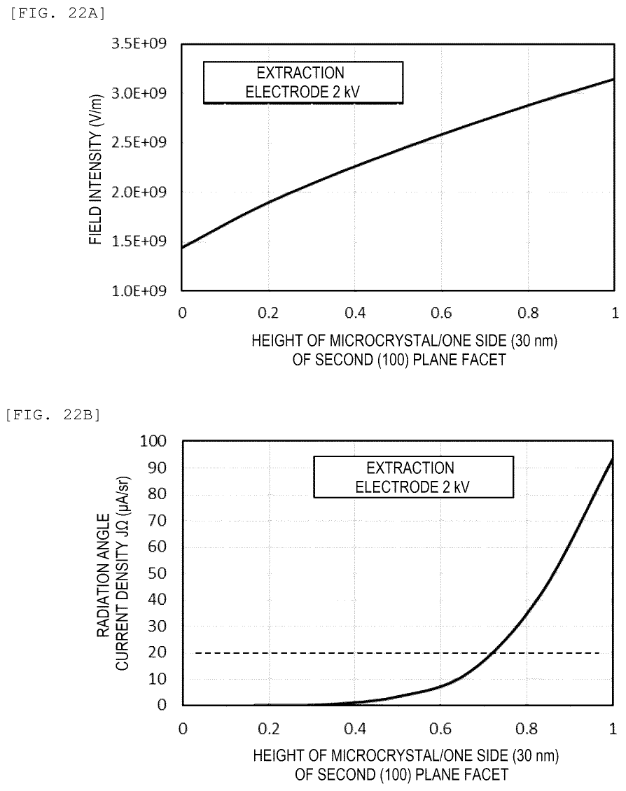

FIGS. 21A-21C are graphs showing changes in electron emission characteristics of a field emission electron source depending on a size (a length of one side) of a microcrystal having a second (100) plane top facet according to Embodiment 5. FIG. 21A is a graph showing a change in a field intensity at the center of a distal end of a tip, FIG. 21B is a graph showing a change in a radiation angle current density J_{Ω} (μA/sr), and FIG. 21C is a graph showing a change in a light source diameter.

FIGS. 21A-21C show how the field intensity at the center of the distal end of the tip 6 (FIG. 21A), the radiation angle current density (FIG. 21B), and the light source diameter in the case of using an electron microscope (FIG. 21C) change depending on a size of a rectangular microcrystal that forms the second (100) plane top facet formed on the plane of the first (100) plane top facet. Here, a size of the (100) plane on the plane of the first top facet 42 is, for example, 170 nm (a regular square shape with a length of 170 nm×a width of 170 nm) as in Embodiment 4. In of FIGS. 21A-21C, an extraction voltage is 2 kV.

First, it has been found that, from a left side in FIG. 21A, the field intensity at the center of the distal end of the tip 6 was approximately 1.5×10⁹ V/m in a case where only the first (100) plane top facet 42 was formed without forming the microcrystal, whereas as the size of the microcrystal of the second (100) plane top facet 43 increased, the field intensity at the center of the distal end of the tip 6 of the second (100) plane top facet 43 increased and reached 3.2×10⁹ V/m when the size of the microcrystals was 20 nm, and then gradually decreased.

The radiation angle current density J_{Ω} (μA/sr) shown in FIG. 21B was maximum at 93 μA/sr when the size of the microcrystal of the second (100) plane top facet 43 was 30 nm. The reason why sizes of the microcrystal at which the field intensity and the radiation angle current density J_{Ω} (μA/sr) are maximum are slightly different is that, even when the field intensity is high, if an area of the second (100) plane top facet 43 serving as an electron emission surface is small, the extracted radiation angle current density J_{Ω} is small. On the other hand, when the size of the microcrystal of the second (100) plane top facet 43 is too large, an electric field is less likely be concentrated, and the radiation angle current density J_{Ω} that can be extracted is reduced. Accordingly, there is an optimal range of the size of the microcrystal of the second (100) plane top facet 43.

Further, FIG. 21C shows how the light source diameter of the field emission electron source changes depending on the size of the microcrystal of the second (100) plane top facet 43. The light source diameter is reduced as the size of the microcrystal is reduced, and resolution of the electron microscope is improved. On the other hand, when there is no microcrystal of the second (100) plane top facet 43, electrons are emitted from the relatively large first (100) plane top facet 42, so that the light source diameter increases.

Based on the above results, it is preferable that the size of the microcrystal of the second (100) plane top facet 43 is not too small and is not too large. Specifically, it is preferable that the size of the microcrystal is in a range of 10 nm to 60 nm at which it is easy to obtain J_{Ω} of 20 μA/sr or more that is generally obtained in a field emission electron source in the related art, and the light source diameter can be reduced to 2 nm or less. Further, it is preferable that the size of the microcrystal is in a range of 20 nm to 40 nm, and J_{Ω}/It that is three times or more of that in the related art can be obtained. In particular, when the size of the microcrystal is 30 nm, J_{Ω}/It that is about four times of that in the related art can be preferably obtained.

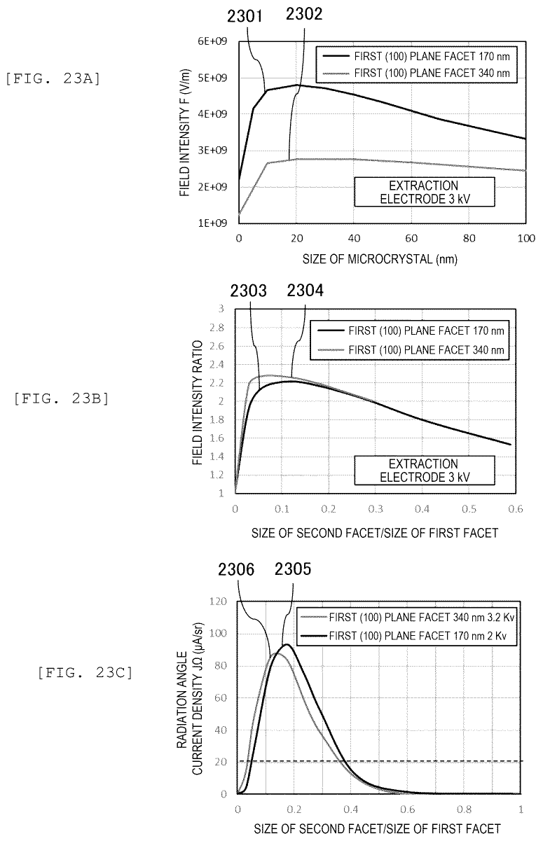

The above studies are conducted in a case where the microcrystal of the second (100) plane top facet 43 has a cubic shape. The microcrystal may have a height different from a length of one side of the second (100) plane top facet 43. Therefore, when the size of the microcrystal (here, defined by a length of one side of the second (100) plane top facet 43) is 30 nm which is an optimal size based on FIGS. 21A-21C, results obtained by studying how the electric field and the radiation angle current density J_{Ω} (μA/sr) change when the height of the microcrystal changes are shown in FIGS. 22A and 22B.

FIGS. 22A and 22B are graphs showing changes in electron emission characteristics of the field emission electron source depending on a ratio of the height of the microcrystal to the length of one side of the second (100) plane top facet according to Embodiment 5, in which FIG. 22A is a graph showing a change in a field intensity at the center of the distal end of the tip, and FIG. 22B is a graph showing a change in the radiation angle current density J_{Ω} (μA/sr). In FIGS. 22A and 22B, an extraction voltage is 2 kV.

As the height to the size (the length of one side) of the microcrystal of the second (100) plane top facet 43 decreases, the field intensity decreases as shown in FIG. 22A, and the radiation angle current density J_{Ω} (μA/sr) decreases as shown in FIG. 22B. Based on FIGS. 22A and 22B, it can be found that, in order to obtain a sufficient effect of electric field concentration by the microcrystal of the second (100) plane top facet 43, the height of the microcrystal of the second (100) plane top facet 43 is preferably 0.7 times or more the size of the microcrystal (the length of one side).

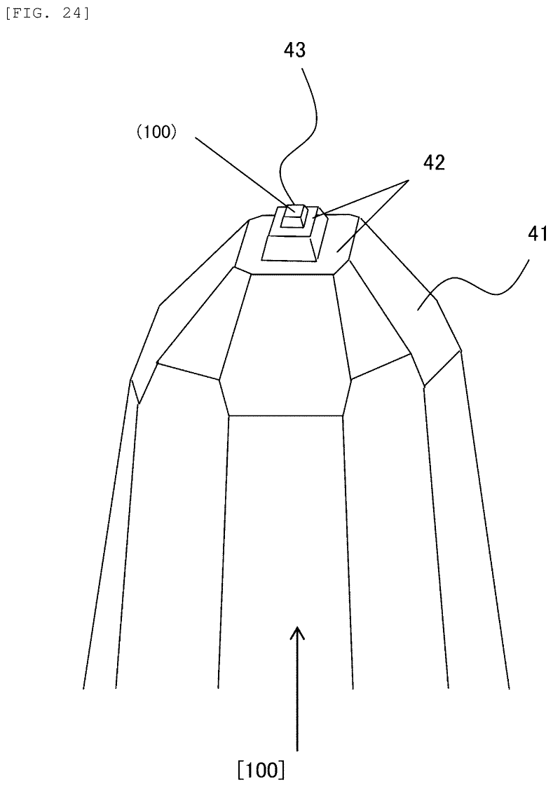

Next, a result obtained by studying a relationship between a size (a length of one side) of the first (100) plane top facet 42 serving as a base and a size (a length of one side) of the second (100) plane top facet 43 serving as an electron emission surface is shown. FIGS. 23A-23C show results obtained by studying a relationship between a case where the length of one side of the first (100) plane top facet is 170 nm and a case where the length of one side is 340 nm according to Embodiment 5. FIG. 23A is a diagram showing a change in the field intensity at the center of the distal end of the tip depending on the size (the length of one side) of the microcrystal having the second (100) plane top facet. FIG. 23B is a diagram showing a change in a field intensity ratio relative to a ratio of the length of one side of the second (100) plane top facet to the length of one side of the first (100) plane top facet. FIG. 23C is a diagram showing a change in the radiation angle current density J_{Ω} (μA/sr) relative to a ratio of the length of one side of the second (100) plane top facet to the length of one side of the first (100) plane top facet. In FIGS. 23A-23C, an extraction voltage is 3 kV.

FIG. 23A shows dependence of the field intensity applied to the tip 6 on the size (the length of one side) of the microcrystal when the size (the length of one side) of the first (100) plane top facet 42 is 170 nm (a line 2301) and when the size (the length of one side) of the first (100) plane top facet 42 is 340 nm which is twice (a line 2302). It can be found that when the size of the first (100) plane top facet 42 serving as a base increases, an electric field is less likely to be concentrated even at the same size of the microcrystal, and therefore, the field intensity is lowered.

FIG. 23B shows a result of studying a normalized field intensity relative to a ratio of the size (the length of one side) of the microcrystal of the second top facet 43 to the size (the length of one side) of the first (100) plane top facet 42. A line 2303 indicates a case where the size of the first (100) plane top facet 42 is 170 nm, and a line 2304 indicates a case where the size of the first (100) plane top facet 42 is 340 nm. A change in the field intensity ratio is substantially determined by a ratio of the size of the microcrystal of the second (100) plane top facet 43 to the size of the first (100) plane top facet 42.

FIG. 23C shows dependence of the radiation angle current density J_{Ω} (μA/sr) on a ratio of the size (the length of one side) of the microcrystal of the second (100) plane top facet 43 to the size (the length of one side) of the first (100) plane top facet 42. A line 2305 indicates a case where the size of the first (100) plane top facet 42 is 170 nm, and a line 2306 indicates a case where the size of the first (100) plane top facet 42 is 340 nm. A case where an extraction voltage was 2 kV when the size of the first top facet 42 was 170 nm and a case where an extraction voltage was 3.2 kV when the size of the facet first (100) plane top facet 42 was 340 nm was compared. It can be found that although extraction voltages are different, when the ratio of the size of the microcrystal of the second (100) plane top facet 43 to the size of the first (100) plane top facet 42 is 0.05 to 0.35, the effect of electric field concentration caused by the microcrystal of the second (100) plane top facet 43 can be effectively utilized. Further, when the ratio of the size of the microcrystal of the second (100) plane top facet 43 to the size of the first (100) plane top facet 42 is set to 0.1 to 0.25, J_{Ω}/It (a ratio of the radiation angle current density J_{Ω} (μA/sr) to the total current It (μA)) that is three times or more that in the related art can be obtained. When the ratio of the size of the microcrystal of the second (100) plane top facet 43 to the size of the first (100) plane top facet 42 is set to 0.15 to 0.2, J_{Ω}/It that is approximately four times that in the related art can be obtained, and it is particularly preferable.

Based on the above results, the following matters were found.
1) The size (the length of one side) of the microcrystal of the second (100) plane top facet 43 is preferably in a range of 10 nm to 60 nm, more preferably in a range of 20 nm to 40 nm, and in particular preferably 30 nm.
2) The height of the microcrystal of the second (100) plane top facet 43 is preferably 0.7 times or more vertical and horizontal sizes (the length of one side) of the microcrystal.
3) The ratio of the size (the length of one side) of the microcrystal of the second (100) plane top facet 43 to the size (the length of one side) of the first (100) plane top facet 42 serving as the base is preferably in a range of 0.05 to 0.35, more preferably in a range of 0.1 to 0.25, and in particular preferably in a range of 0.15 to 0.2.
4) The microcrystal that forms the second (100) plane top facet 43 has a cubic shape in which side surfaces are formed by the {100} plane group, or a trapezoidal shape in which the side surfaces are formed by the {111} plane group.

### Embodiment 6

In Embodiments 2 to 5 described above, a case in which the first (100) plane top facet 42 serving as a base has one stage was described. In practice, it is also possible to form the first (100) plane top facet 42 in a multistage structure by the electric field, the temperature, and the maintaining time applied in the second thermal field processing in Embodiment 2 and Embodiment 3. When the first (100) plane top facet 42 has a multistage structure, the number of stages of diffusion barriers for an adsorption gas diffused on side walls of the tip 6 increases, and stability of an emission current is further improved.

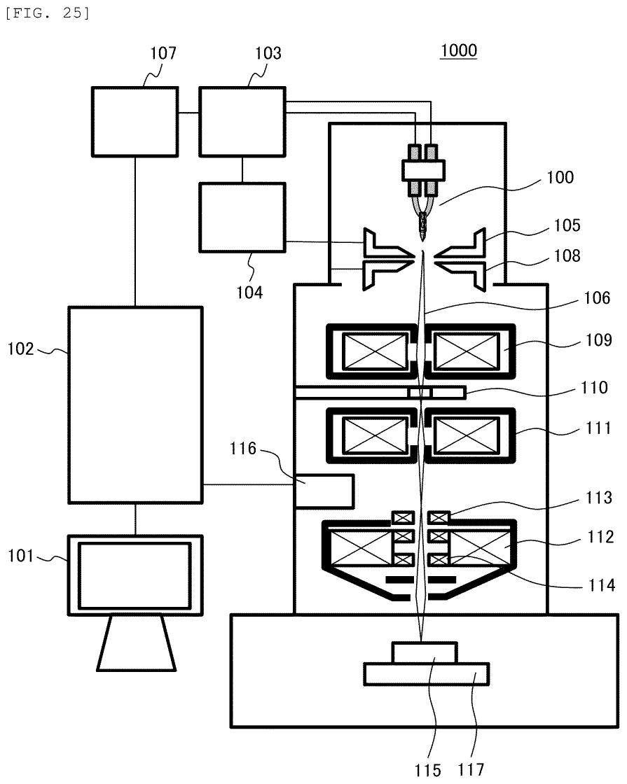

FIG. 24 is a perspective view showing a tip on which the first (100) plane top facet 42 on a distal end of the tip is formed to have a multistage structure according to Embodiment 6.

FIG. 24 is a structural diagram showing a field emission electron source when the first (100) plane top facet 42 has two stages. In this case, similar to Embodiment 5, the size (the length of one side) of the microcrystal of the second (100) plane top facet 43 at the most top portion is preferably in a range of 10 nm to 60 nm, more preferably 20 nm to 40 nm, and in particular preferably 30 nm, and a ratio of the size of the second (100) plane top facet 43 of the microcrystal at the most top portion to the size of the first (100) plane top facet 42 serving as a base is preferably in a range of 0.05 to 0.35, more preferably in a range of 0.1 to 0.25, and in particular preferably in a range of 0.15 to 0.2.

Since this relationship is the same even when the number of stages increases, as the number of stages increases, the size of the (100) plane top facet 42 at a lowermost stage increases, and a diameter of the tip 6 increases. Specifically, when the size of the microcrystal of the second (100) plane top facet 43 is 10 nm which is the smallest in the preferable range, and the ratio of the size of the microcrystal of the second (100) plane top facet 43 to the size of the first (100) plane top facet 42 is 0.35 which is the largest in the preferable range, the diameter of the tip 6 exceeds 1.5 μm in a case where the first (100) plane top facet has 5 or more stages. In this case, an extraction voltage required for obtaining field emission electrons becomes too high, and it is difficult to operate an electron microscope under a restriction of a high-voltage power supply used in the electron microscope and a limitation of a withstand voltage between electrodes. Therefore, it is preferable that the number of stages of the first (100) plane top facet 42 is four or less.

### Embodiment 7

Embodiment 7 will be described with reference to FIG. 25. FIG. 25 is a schematic sectional view showing an electron beam device according to Embodiment 7 (a scanning electron microscope equipped with a field emission electron source using a tip of a hexaboride single crystal or a transition metal carbide according to the invention).

Embodiment 7 shows an example of a scanning electron microscope 1000 equipped with the electron source (the field emission electron source) 100 using, as an electron emission surface, the second (100) plane top facet 43 of the tip 6 of the transition metal carbide single crystal of HfC that is evaluated in Embodiment 4. In the present embodiment, when a hexaboride single crystal such as CeB₆ is used, the same effect can be obtained.

FIG. 25 is a schematic view showing the scanning electron microscope 1000 that is an electron beam device according to Embodiment 7. The field emission electron source 100 is constantly heated by applying a constant current to a heating power supply 103 controlled by a computer 101 and a controller 102, and an extraction power supply 104 applies a positive voltage to an extraction electrode 105 and applies a positive voltage to the tip 6 of the field emission electron source 100 to emit electrons by field emission.

An emitted electron beam 106 is accelerated toward a grounded anode 108 by a negative high-voltage applied by an acceleration power supply 107, focused by a first condenser lens 109, a diaphragm 110, a second condenser lens 111, an objective lens 112, and an astigmatism correction coil 113, is subject to scanning performed by a deflection scanning coil 114, and is radiated onto an observation region on a sample 115, and generated secondary electrons are detected by a secondary electron detector 116. Although detectors other than the secondary electron detector are not shown, other reflected electron detectors, element analyzers, and the like are also used.

That is, the scanning electron microscope 1000 includes the field emission electron source 100, a sample stage 117 on which the sample 115 is placed, and an electron optical system that focuses electrons emitted from the field emission electron source 100 into a beam shape and irradiates the sample 115 on the sample stage 117 with the electrons.

Electrons are emitted from the field emission electron source 100 using the (100) plane of the tip 6 of HfC as an electron emission surface. Since the work function of HfC is about 3.3 eV and is lower than 4.3 eV of a field emission electron source using the {310} planes of W, the emitted electrons have a narrow energy full width at half maximum and good monochromaticity. Therefore, chromatic aberration in the objective lens 112 and the like is reduced, and the sample 115 can be irradiated with the more focused electron beam 106. Accordingly, a high-resolution scanning electron microscope image can be obtained. When CeB₆ is used, the work function is about 2.6 eV. Since the work function is lower than 4.3 eV of the field emission electron source using the {310} planes of W, the same effect can be obtained with further narrowed energy full width at half maximum.

Since the field emission electron source 100 according to the invention uses electrons emitted from the second (100) plane top facet 43 of the microcrystal having a small area, a light source diameter is small, which contributes to improvement of resolution. As compared with an electron source in the related art, J_{Ω}/It (the ratio of the radiation angle current density J_{Ω} (μA/sr) to the total current It (μA)) is 4 times or more, and a current outside an optical axis can be reduced. Therefore, an amount of unnecessary electrons that are radiated onto members around the electron source can be reduced. Further, it is possible to prevent generation of an electron beam stimulation desorption gas from an electrode and improve stability of the field emission electron source 100. Further, since the step of the microcrystal serves as a barrier for the adsorption gas that surface-diffuses on the side walls of the tip 6, arrival of the adsorption gas to the second (100) plane top facet 43 can be delayed, and thus stability of the field emission electron source 100 can be further improved. Therefore, a work interval of flushing processing required for cleaning a surface of the field emission electron source 100 can be increased, and stable measurement can be performed over a long time.

Since the field emission electron source 100 according to the invention has J_{Ω}/It that is four times or more an electron source in the related art, it is also possible to obtain a large radiation angle current density. In particular, when an element analysis or the like is performed, a large radiation angle current density is required to shorten an analysis time, which is effective.

The embodiments described above has been described in detail to facilitate understanding of the invention, and the invention is not necessarily limited to those including all the configurations described above. A part of a configuration in one embodiment can be replaced with a configuration in another embodiment, and a configuration in one embodiment can also be added to a configuration in another embodiment. In addition, a part of a configuration in each embodiment may be added to, deleted from, or replaced with another configuration.

### REFERENCE SIGNS LIST

1: metal atom
2: boron atom
3: carbon atom
4: single crystal
5: rod
6: tip
11: metal tube
12: guide pin
13: base
14: paste
15: blade
16: stereo microscope
17: recessed portion
18: filament
19: stem
20: electrode
21-1, 21-2: positioning jig
22: electrolytic solution
23: counter electrode
24: power supply
25: container
41: side facet
42: first top facet
43: second top facet
100: field emission electron source
101: computer
102: controller
103: heating power supply
104: extraction power supply
105: extraction electrode
106: electron beam
107: acceleration power supply
108: anode
109: first condenser lens
110: diaphragm
111: second condenser lens
112: objective lens
113: astigmatism correction coil
114: deflection scanning coil
115: sample
116: secondary electron detector
117: sample stage
150: protrusion
151 to 156: process regions of tip of hexaboride single crystal
161 to 165: process regions of tip of transition metal carbide single crystal
200, 201: simple cubic lattice
1000: scanning electron microscope
1001: structure

1. A field emission electron source, wherein a first (100) plane top facet is formed at a distal end of a tip of a hexaboride single crystal or a transition metal carbide single crystal with a <100> axis, the first (100) plane top facet is surrounded by side facets that include at least four {n11} planes and at least four {n10} planes, n being an integer of 1, 2, or 3, and of which a total area of {n11} plane side facets is larger than a total area of {n10} plane side facets, further, a microcrystal having a second (100) plane top facet is formed on a plane of the first (100) plane top facet, and electrons are mainly emitted from the second (100) plane top facet.

2. The field emission electron source according to claim 1, wherein
the hexaboride single crystal is a single crystal having LaB₆ or CeB₆ as a main component.

3. The field emission electron source according to claim 1, wherein
the transition metal carbide single crystal is a single crystal having HfC, ZrC or TiC as a main component.

4. The field emission electron source according to claim 1, wherein
the {n11} plane of the tip of the hexaboride single crystal or the transition metal carbide single crystal has a higher work function than the {n10} plane.

5. The field emission electron source according to claim 1, wherein
the second (100) plane top facet of the microcrystal is smaller than the first (100) plane top facet.

6. The field emission electron source according to claim 1, wherein
the microcrystal has a cubic shape in which a top portion and side portions are formed by {100} planes, or a trapezoidal shape in which a top facet is formed by a (100) plane and side portions are formed by {111} planes.

7. The field emission electron source according to claim 1, wherein
a ratio of a length of one side of the second (100) plane top facet of the microcrystal to a length of one side of the first (100) plane top facet is in a range of 0.05 to 0.35.

8. The field emission electron source according to claim 1, wherein
a length of one side of the second (100) plane top facet of the microcrystal is in a range of 10 nm to 60 nm.

9. The field emission electron source according to claim 1, wherein
a height of the microcrystal is 0.7 times or more a length of one side of the second (100) plane top facet.

10. The field emission electron source according to claim 1, wherein
the first (100) plane top facet has a multistage structure of four or less stages.

11. A method of producing a field emission electron source, comprising:
applying a high electric field to a tip at a high temperature and with the tip in a positive polarity, the tip being a hexaboride single crystal or a transition metal carbide single crystal whose longitudinal direction is a [100] orientation, thereby causing building up due to movement of atoms toward a distal end of the tip and forming a first (100) plane top facet; and
thereafter lowering the electric field applied to the tip, thereby growing a microcrystal having a second (100) plane top facet on a plane of the first (100) plane top facet.

12. An electron beam device comprising:
an electron source;
a sample stage configured to allow a sample to be placed; and
an electron optical system configured to focus electrons emitted from the electron source into a beam shape and irradiate a sample on the sample stage with the focused electrons, wherein
the electron source is a field emission electron source in which a first (100) plane top facet is formed at a distal end of a tip of a hexaboride single crystal or a transition metal carbide single crystal with a <100> axis, the first (100) plane top facet is surrounded by side facets that include at least four {n11} planes and at least four {n10} planes, n being an integer of 1, 2, or 3, and of which a total area of {n11} plane side facets is larger than a total area of {n10} plane side facets, further a microcrystal having a second (100) plane top facet is formed in a plane of the first (100) plane top facet, and electrons are emitted from the second (100) plane top facet.
